(19) United States
(12) Patent Application Publication
(10) Pub. No.: US 2023/0328949 A1
(43) Pub. Date: Oct. 12, 2023

(54) PILLAR-SHAPED SEMICONDUCTOR DEVICE AND MANUFACTURING METHOD THEREOF

(71) Applicant: Unisantis Electronics Singapore Pte. Ltd., Singapore (SG)

(72) Inventor: Kenichi KANAZAWA, Tokyo (JP)

(21) Appl. No.: 18/332,968

(22) Filed: Jun. 12, 2023

Related U.S. Application Data
(63) Continuation of application No. PCT/JP2020/046526, filed on Dec. 14, 2020.

(51) Int. Cl. H10B 10/00; H01L 29/423; H01L 29/36

(52) U.S. Cl. CPC H10B 10/125; H01L 29/42392; H01L 29/36

(57) ABSTRACT

In a method of forming a gate conductor layer which surrounds a semiconductor pillar, a first impurity region and a first mask material layer having oxidation resistance are respectively formed in a top part of a semiconductor pillar and on a side wall of the semiconductor pillar, thermal or chemical oxidation is performed on the entire stack, a first insulation layer is formed on the exposed surface of the first impurity region, the first mask material layer is removed, and a gate conductor layer is formed in an upper part of the first insulation layer.

The present application is a Continuation application of PCT/JP2020/046526, filed Dec. 14, 2020, the entire contents of which are incorporated herein by reference.

### BACKGROUND OF THE INVENTION

### Field of the Invention

The present invention relates to a pillar-shaped semiconductor device and to a manufacturing method thereof.

### Description of the Related Art

In recent years, three-dimensional transistors are used in LSI (Large Scale Integration). Among such three-dimensional transistors, an SGT (Surrounding Gate Transistor) which is a pillar-shaped semiconductor device is garnering attention as a semiconductor element that provides a highly-integrated semiconductor device. In addition, there is a need for higher integration and higher performance of semiconductor devices having an SGT.

With an ordinary planar MOS transistor, a channel extends in a horizontal direction along an upper surface of a semiconductor substrate. In contrast, a channel of an SGT extends in a vertical direction relative to the upper surface of the semiconductor substrate (for example, refer to Japanese Patent Laid-Open No. H2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Therefore, an SGT enables further densification of a semiconductor device as compared to a planar MOS transistor.

FIG. 13 shows a schematic structural diagram of an N channel SGT. N⁺ layers 221a and 221b (hereinafter, a semiconductor region containing a high concentration of donor impurities will be referred to as an “N⁺ layer”), one of which serves as a drain when the other serves as a source, are formed at upper and lower positions inside a Si pillar 220 (hereinafter, a silicon semiconductor pillar will be referred to as a “Si pillar”) having a P or i (intrinsic) conductivity type. A portion of the Si pillar 220 between the N⁺ layers 221a and 221b, which are to serve as a source and a drain, serves as a channel region 222. A gate insulating layer 223 is formed so as to surround the channel region 222. A gate conductor layer 224 is formed so as to surround the gate insulating layer 223. In the SGT, the N⁺ layers 221a and 221b to serve as a source and a drain, the channel region 222, the gate insulating layer 223, and the gate conductor layer 224 are formed in a pillar shape as a whole. Therefore, an occupied area of the SGT in a plan view corresponds to an occupied area of a single source or drain N⁺ layer of a planar MOS transistor. Therefore, a circuit chip having an SGT enables a further reduction in chip size as compared to a circuit chip having a planar MOS transistor. In addition, if a drive capability of the SGT can be improved, the number of SGTs used in one chip can be reduced and a similar contribution can be made toward reducing chip size.

Although advantageous for realizing a higher integration as described earlier, SGTs with a vertical structure suffer from problems unique to them. While a gate length and an effective channel length in a conventional transistor with a planar-type structure are mainly determined by accuracy of photolithography, a gate length and an effective channel length in an SGT are mainly determined by variation in film forming and machining accuracy of etching or CMP.

While the accuracy of photolithography is approaching accuracy on the order of nanometers due to recent progress made in exposure equipment and resist agents, with respect to forming and machining material layers, particularly those which are thick by etching or CMP, accuracy has not yet reached a level where a thickness of film formation, an amount of etching, and an amount of polishing by CMP can be controlled on the order of nanometers. Therefore, in SGTs, how much variation in gate length and effective channel length can be reduced is a major issue.

FIG. 14 shows an SRAM (Static Random Access Memory) cell circuit diagram. The present SRAM cell circuit includes two inverter circuits. One of the inverter circuits is constituted of a P channel SGT Pc1 as a load transistor and an N channel SGT Nc1 as a drive transistor. The other inverter circuit is constituted of a P channel SGT Pc2 as a load transistor and an N channel SGT Nc2 as a drive transistor. A gate of the P channel SGT Pc1 and a gate of the N channel SGT Nc1 are connected to each other. A drain of the P channel SGT Pc2 and a drain of the N channel SGT Nc2 are connected to each other. A gate of the P channel SGT Pc2 and a gate of the N channel SGT Nc2 are connected to each other. A drain of the P channel SGT Pc1 and a drain of the N channel SGT Nc1 are connected to each other.

As shown in FIG. 14, sources of the P channel SGTs Pc1 and Pc2 are connected to a power supply terminal Vdd. Sources of the N channel SGTs Nc1 and Nc2 are connected to a ground terminal Vss. Selective N channel SGTs SN1 and SN2 are arranged on both sides of the two inverter circuits. Gates of the selective N channel SGTs SN1 and SN2 are connected to a word line terminal WLt. A source and a drain of the selective N channel SGT SN1 are connected to drains of the N channel SGT Nc1 and the P channel SGT Pc1 and to a bit line terminal BLt. A source and a drain of the selective N channel SGT SN2 are connected to drains of the N channel SGT Nc2 and the P channel SGT Pc2 and to an inverted bit line terminal BLRt. In this manner, a circuit having an SRAM cell is constituted of a total of six SGTs including two P channel SGTs Pc1 and Pc2 and four N channel SGTs Nc1, Nc2, SN1, and SN2 (for example, refer to U.S. Patent Application Publication No. 2010/0219483). In addition, an operation speed of the SRAM circuit can be increased by connecting a plurality of the drive transistors in parallel. Normally, each SGT constituting a memory cell of an SRAM is formed on a different semiconductor pillar. An important element in realizing stable operation and higher quality of an SRAM cell circuit is to suppress variations in operation and operational failures of each SGT. This similarly applies to the formation of other circuits using SGTs.

Variations in a gate length and an effective channel length in a circuit using SGTs result in occurrences of characteristic variations and operational failures.

### SUMMARY OF THE INVENTION

A manufacturing method of a pillar-shaped semiconductor device according to an aspect of the present invention includes,
in manufacturing a pillar-shaped semiconductor device including a SGT including, on an upper part of a substrate, a semiconductor pillar, a gate insulating layer surrounding the semiconductor pillar, a gate conductor layer surrounding the gate insulating layer, a first impurity region connected to a lower part of the semiconductor pillar, and a second impurity region connected to a top part of the semiconductor pillar, the semiconductor pillar between the first impurity region and the second impurity region constituting a channel, the steps of:
forming the first impurity region containing donor or acceptor impurities on a surface of the substrate;
forming the semiconductor pillar on the first impurity region;
coating an entire surface with a first mask material layer;
leaving the first mask material layer on a side wall of the semiconductor pillar and exposing a surface of the first impurity region by anisotropic etching of the first mask material layer;
applying thermal or chemical oxidation to an entire stack and forming a first insulation layer on the exposed surface of the first impurity region;
removing the first mask material layer left on the side wall of the semiconductor pillar by isotropic etching;
forming the gate insulating layer which surrounds the semiconductor pillar and the gate conductor layer which further surrounds the gate insulating layer; and forming the second impurity region in a top part of the semiconductor pillar.

Desirably, in the manufacturing method described above,
a film thickness of the first insulation layer is set so that the film thickness of the first insulation layer is thicker than a film thickness of the gate insulating layer and a position of a lower end of the gate conductor layer is a same position as or a lower position than an upper end position of the first impurity region in the semiconductor pillar.

Desirably, in the manufacturing method described above,
a film thickness of the first mask material layer is smaller than a film thickness that is twice the film thickness of the gate insulating layer.

Desirably, the manufacturing method described above
further includes a step of, after subjecting the first mask material layer to anisotropic etching, implanting at least one of oxygen ions and impurities of a same conductivity type as the first impurity region by an ion implantation method to the entire exposed surface of the first impurity region.

Desirably, in the manufacturing method described above,
after forming the first insulation layer, impurities of a same conductivity type as the first impurity region are implanted by an ion implantation method to an entire region below the first insulation layer with energy that enables a sufficient amount of the impurities to be implanted.

Desirably, the manufacturing method described above
further includes a step of, after subjecting the first mask material layer to anisotropic etching, forming a semiconductor layer by selective epitaxial growth on an exposed surface of the substrate, wherein
the step of forming the first insulation layer involves forming the first insulation layer on the exposed surface of the substrate by thermally or chemically oxidizing the entire semiconductor layer.

Desirably, in the manufacturing method described above,
an oxide film growth rate of the thermal or chemical oxidation of the semiconductor layer is greater than an oxide film growth rate of the thermal or chemical oxidation of the first impurity region.

Desirably, in the manufacturing method described above,
the semiconductor layer is doped with impurities of a same conductivity type as the first impurity region during epitaxial growth.

Desirably, in the manufacturing method described above,
after forming the semiconductor layer, at least one of oxygen ions and impurities of a same conductivity type as the first impurity region are implanted by an ion implantation method to the entire semiconductor layer.

Desirably, in the manufacturing method described above,
a film thickness of the semiconductor layer is set such that, after forming the semiconductor layer, the first insulation layer with a desired film thickness can be formed by performing thermal or chemical oxidation which enables the entire semiconductor layer to be changed to an oxide film.

A manufacturing method of a pillar-shaped semiconductor device according to another aspect of the present invention includes,
in manufacturing a pillar-shaped semiconductor device including a SGT including, on an upper part of a substrate, a semiconductor pillar, a gate insulating layer surrounding the semiconductor pillar, a gate conductor layer surrounding the gate insulating layer, a first impurity region connected to a lower part of the semiconductor pillar, and a second impurity region connected to a top part of the semiconductor pillar, the semiconductor pillar between the first impurity region and the second impurity region constituting a channel, the steps of:
forming the semiconductor pillar on the first impurity region and forming a second mask material layer in a top part of the semiconductor pillar;
forming the gate insulating layer which surrounds the semiconductor pillar;
forming the gate conductor layer which surrounds the gate insulating layer;
coating an entire surface with a second insulation layer at a film thickness which exceeds a height of a surface of the second mask material layer;
polishing and planarizing the second insulation layer so as to expose the surface of the second mask material layer;
removing the exposed second mask material layer to expose the top part of the semiconductor pillar; and
forming the second impurity region in the exposed top part of the semiconductor pillar.

Desirably, in the manufacturing method described above,
a film thickness of the second mask material layer is set so that a position of an upper end of the gate conductor layer is the same position as or a higher position than a position of a lower end of the second mask material layer.

Desirably, in the manufacturing method described above,
a third mask material layer is formed in the top part of the semiconductor pillar and the second mask material layer is formed in an upper part of the third mask material layer.

Desirably, in the manufacturing method described above,
film thicknesses of the first and third mask material layers are set so that a position of a lower end of the third mask material layer is the same position as or a lower position than a position of the upper end of the gate conductor layer.

A manufacturing method of a pillar-shaped semiconductor device according to yet another aspect of the present invention includes,
in manufacturing a pillar-shaped semiconductor device including a SGT including, on an upper part of a substrate, a semiconductor pillar, a gate insulating layer surrounding the semiconductor pillar, a gate conductor layer surrounding the gate insulating layer, a first impurity region connected to a lower part of the semiconductor pillar, and a second impurity region connected to a top part of the semiconductor pillar, the semiconductor pillar between the first impurity region and the second impurity region constituting a channel, the steps of:
forming the first impurity region containing donor or acceptor impurities on a surface of the substrate;
forming the semiconductor pillar on the first impurity region and forming a second mask material layer in a top part of the semiconductor pillar;
coating an entire surface with a first mask material layer;
leaving the first mask material layer on a side wall of the semiconductor pillar and leaving the second mask material layer in the top part of the semiconductor pillar in a plan view while exposing a surface of the first impurity region in regions other than the semiconductor pillar by anisotropic etching of the first mask material layer;
applying thermal or chemical oxidation to an entire stack and forming a first insulation layer on the exposed surface of the first impurity region;
removing the first mask material layer left on the side wall of the semiconductor pillar by isotropic etching;
forming the gate insulating layer which surrounds the semiconductor pillar and the gate conductor layer which further surrounds the gate insulating layer;
coating an entire surface with a second insulation layer at a film thickness which exceeds a height of the semiconductor pillar;
polishing and planarizing the second insulation layer so as to expose the surface of the second mask material layer in the top part of the semiconductor pillar;
removing the exposed second mask material layer to expose the top part of the semiconductor pillar; and
forming the second impurity region in the exposed top part of the semiconductor pillar.

### BRIEF DESCRIPTION OF THE DRAWINGS

FIGS. 1AA to 1AC is a plan view and a sectional structural diagram for explaining a manufacturing method of a pillar-shaped semiconductor device having an SGT according to a first embodiment;

FIGS. 1BA to 1BC is a plan view and a sectional structural diagram for explaining the manufacturing method of a pillar-shaped semiconductor device having an SGT according to the first embodiment;

FIGS. 1CA to 1CC is a plan view and a sectional structural diagram for explaining the manufacturing method of a pillar-shaped semiconductor device having an SGT according to the first embodiment;

FIGS. 1DA to 1DC is a plan view and a sectional structural diagram for explaining the manufacturing method of a pillar-shaped semiconductor device having an SGT according to the first embodiment;

FIGS. 1EA to 1EC is a plan view and a sectional structural diagram for explaining the manufacturing method of a pillar-shaped semiconductor device having an SGT according to the first embodiment;

FIGS. 1FA to 1FC is a plan view and a sectional structural diagram for explaining the manufacturing method of a pillar-shaped semiconductor device having an SGT according to the first embodiment;

FIGS. 1GA to 1GC is a plan view and a sectional structural diagram for explaining the manufacturing method of a pillar-shaped semiconductor device having an SGT according to the first embodiment;

FIGS. 1HA to 1HC is a plan view and a sectional structural diagram for explaining the manufacturing method of a pillar-shaped semiconductor device having an SGT according to the first embodiment;

FIGS. 1IA to 1IC is a plan view and a sectional structural diagram for explaining the manufacturing method of a pillar-shaped semiconductor device having an SGT according to the first embodiment;

FIGS. 1JA to 1JC is a plan view and a sectional structural diagram for explaining the manufacturing method of a pillar-shaped semiconductor device having an SGT according to the first embodiment;

FIGS. 1KA to 1KC is a plan view and a sectional structural diagram for explaining the manufacturing method of a pillar-shaped semiconductor device having an SGT according to the first embodiment;

FIGS. 1LA to 1LC is a plan view and a sectional structural diagram for explaining the manufacturing method of a pillar-shaped semiconductor device having an SGT according to the first embodiment;

FIGS. 1MA to 1MC is a plan view and a sectional structural diagram for explaining the manufacturing method of a pillar-shaped semiconductor device having an SGT according to the first embodiment;

FIGS. 2A to 2D is a sectional structural diagram and an enlarged view of main parts for explaining a manufacturing method of a pillar-shaped semiconductor device having an SGT according to a second embodiment of the present invention;

FIGS. 3A to 3D is a sectional structural diagram and an enlarged view of main parts for explaining a manufacturing method of a pillar-shaped semiconductor device having an SGT according to a third embodiment of the present invention;

FIGS. 4A to 4C is a sectional structural diagram for explaining a manufacturing method of a pillar-shaped semiconductor device having an SGT according to a fourth embodiment of the present invention;

FIGS. 5A to 5C is a plan view and a sectional structural diagram for explaining a manufacturing method of a pillar-shaped semiconductor device having an SGT according to a fifth embodiment of the present invention;

FIGS. 6AA to 6AC is a plan view and a sectional structural diagram for explaining a manufacturing method of a pillar-shaped semiconductor device having an SGT according to sixth, seventh, and eighth embodiments of the present invention;

FIGS. 6BA to 6BC is a plan view and a sectional structural diagram for explaining the manufacturing method of a pillar-shaped semiconductor device having an SGT according to the sixth, the seventh, and the eighth embodiments of the present invention;

FIGS. 7A to 7C is a plan view and a sectional structural diagram for explaining a manufacturing method of a pillar-shaped semiconductor device having an SGT according to a ninth embodiment of the present invention;

FIGS. 8A to 8C is a plan view and a sectional structural diagram for explaining a manufacturing method of a pillar-shaped semiconductor device having an SGT according to a tenth embodiment of the present invention;

FIGS. 9AA to 9AC is a plan view and a sectional structural diagram for explaining a manufacturing method of a pillar-shaped semiconductor device having an SGT according to an eleventh embodiment of the present invention;

FIGS. 9BA to 9BC is a plan view and a sectional structural diagram for explaining the manufacturing method of a pillar-shaped semiconductor device having an SGT according to the eleventh embodiment of the present invention;

FIGS. 9CA to 9CC is a plan view and a sectional structural diagram for explaining the manufacturing method of a pillar-shaped semiconductor device having an SGT according to the eleventh embodiment of the present invention;

FIGS. 10A to 10D is a sectional structural diagram and an enlarged view of main parts for explaining a manufacturing method of a pillar-shaped semiconductor device having an SGT according to a twelfth embodiment of the present invention;

FIGS. 11AA to 11AC is a plan view and a sectional structural diagram for explaining a manufacturing method of a pillar-shaped semiconductor device having an SGT according to a thirteenth embodiment of the present invention;

FIGS. 11BA to 11BC is a plan view and a sectional structural diagram for explaining the manufacturing method of a pillar-shaped semiconductor device having an SGT according to the thirteenth embodiment of the present invention;

FIGS. 12A to 12D is a sectional structural diagram and an enlarged view of main parts for explaining a manufacturing method of a pillar-shaped semiconductor device having an SGT according to a fourteenth embodiment of the present invention;

FIG. 13 is a schematic structural diagram showing an SGT according to a conventional example; and

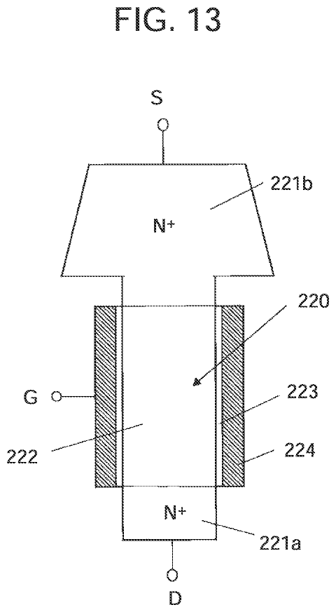

FIG. 14 is an SRAM cell circuit diagram using an SGT according to a conventional example.

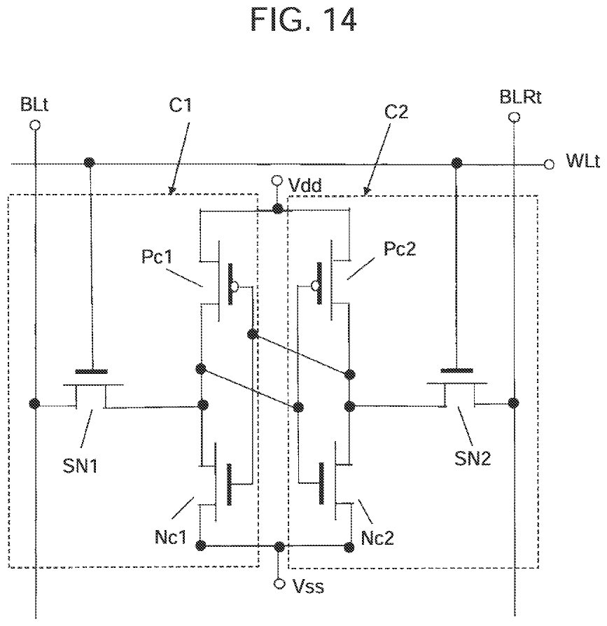

### DETAILED DESCRIPTION OF THE PREFERRED EMBODIMENTS

Hereinafter, a manufacturing method of a pillar-shaped semiconductor device according to embodiments of the present invention will be described with reference to the drawings.

### First Embodiment

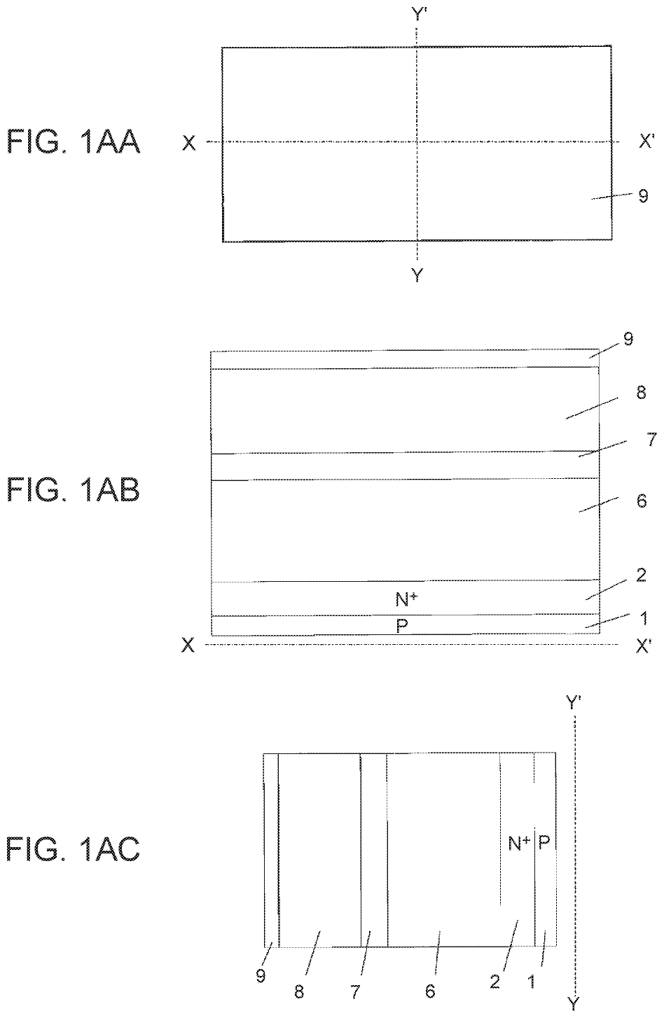

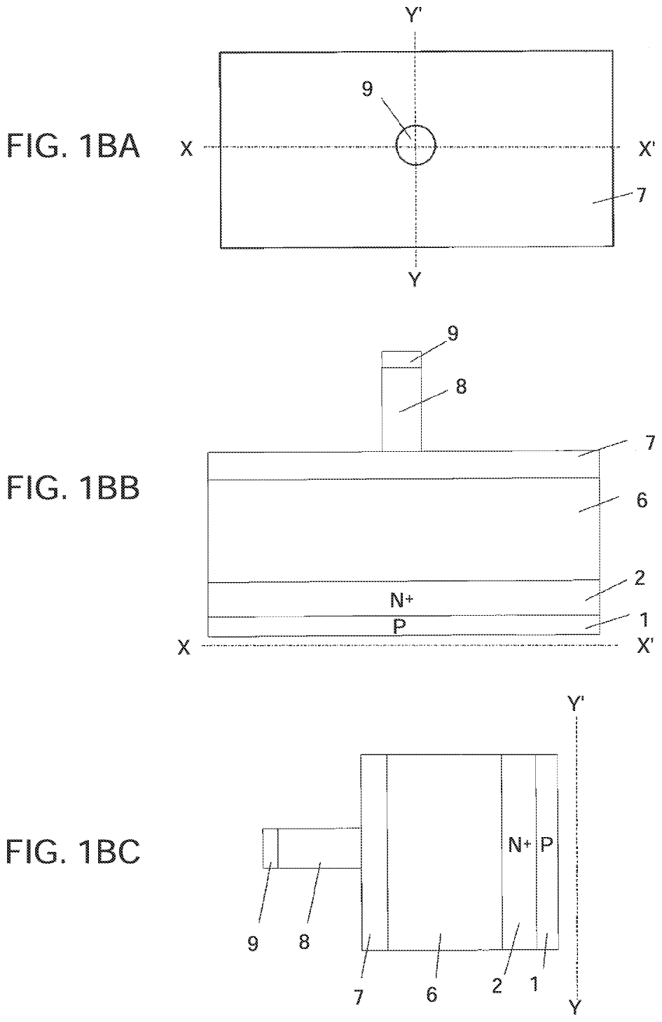

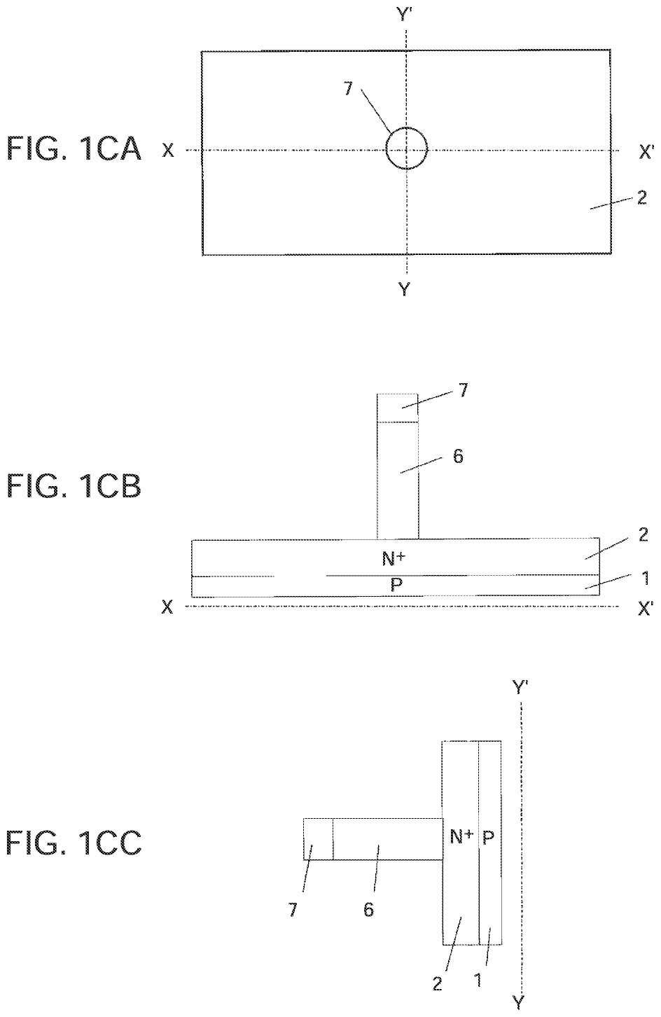

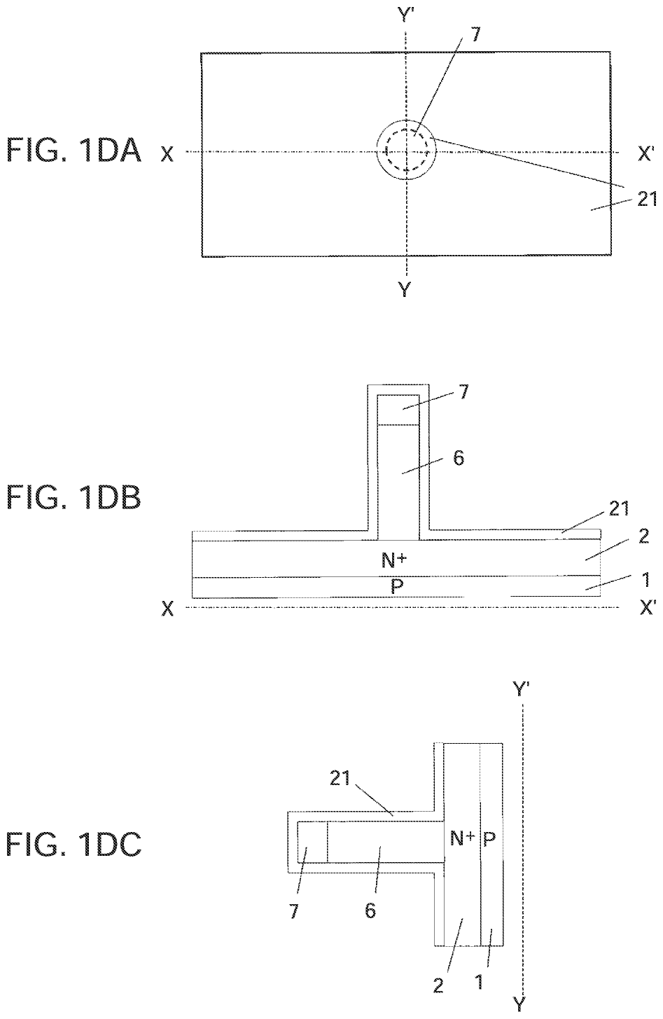

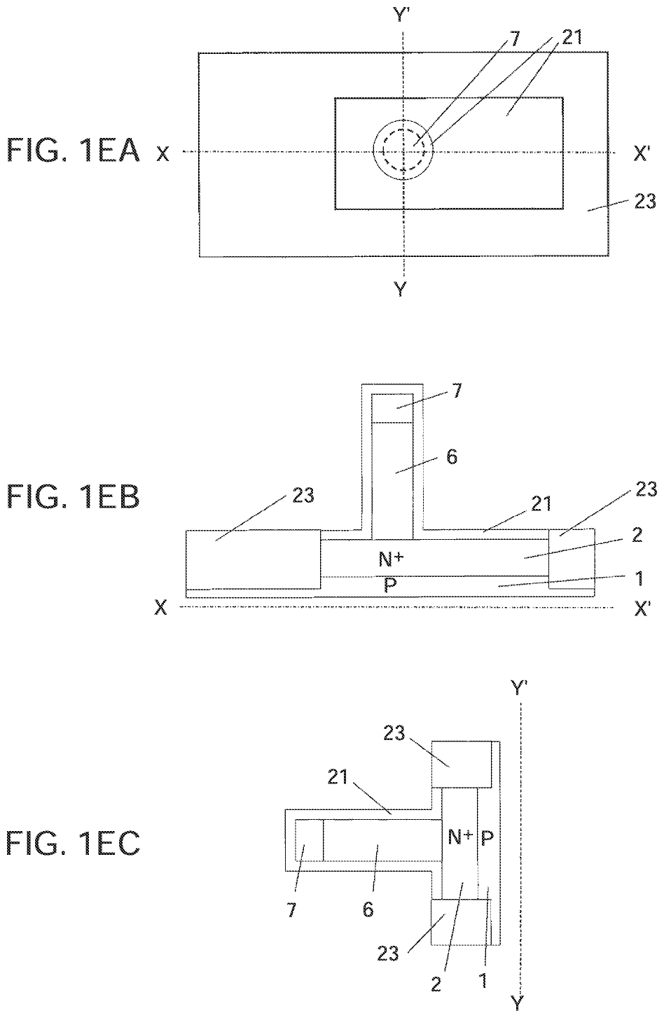

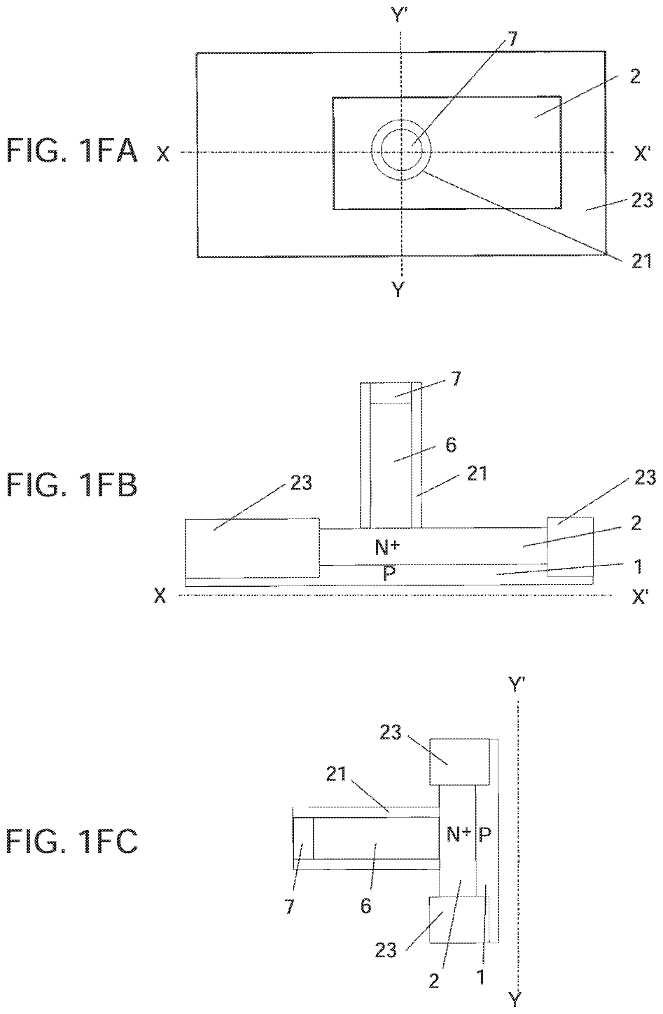

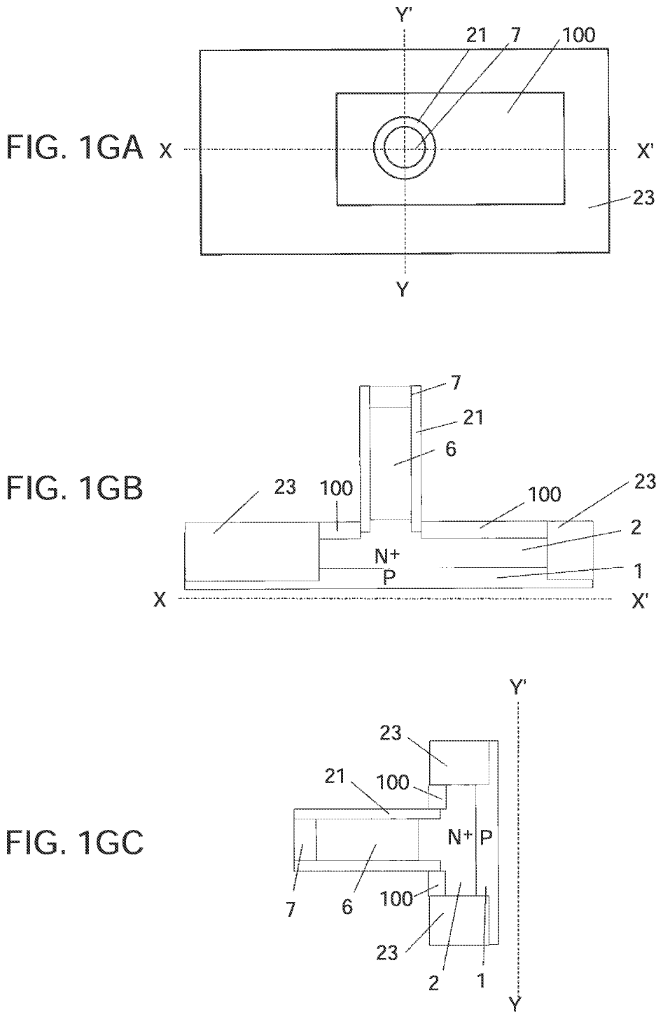

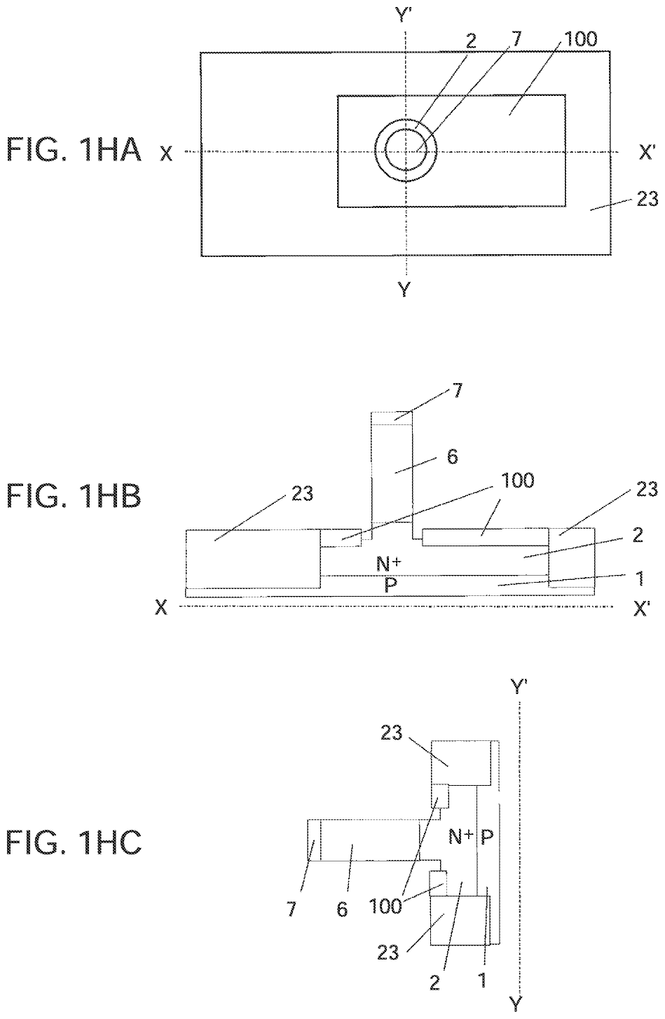

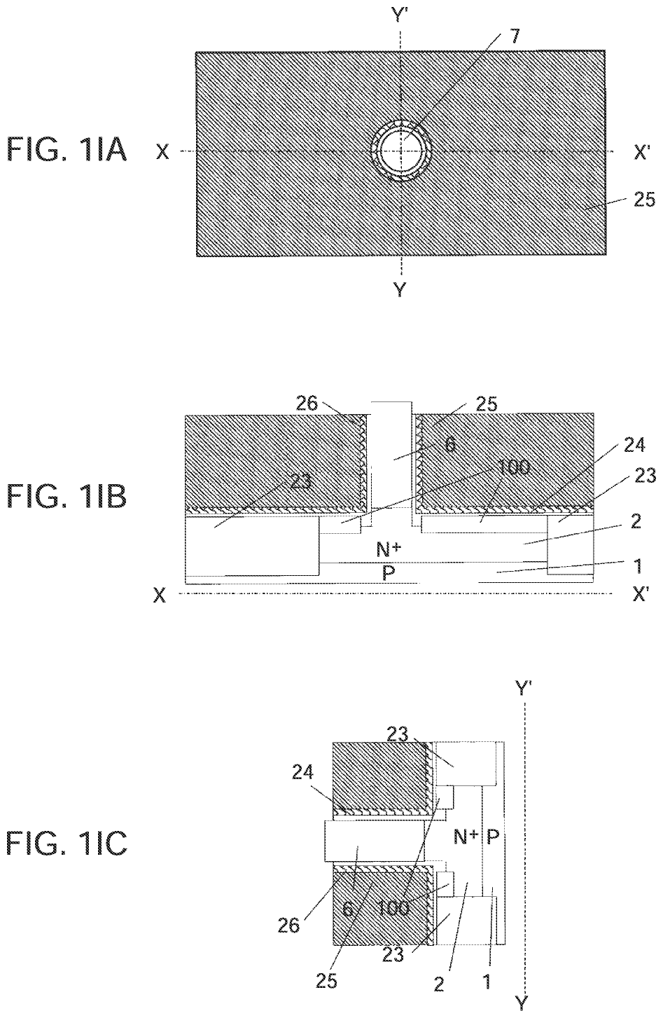

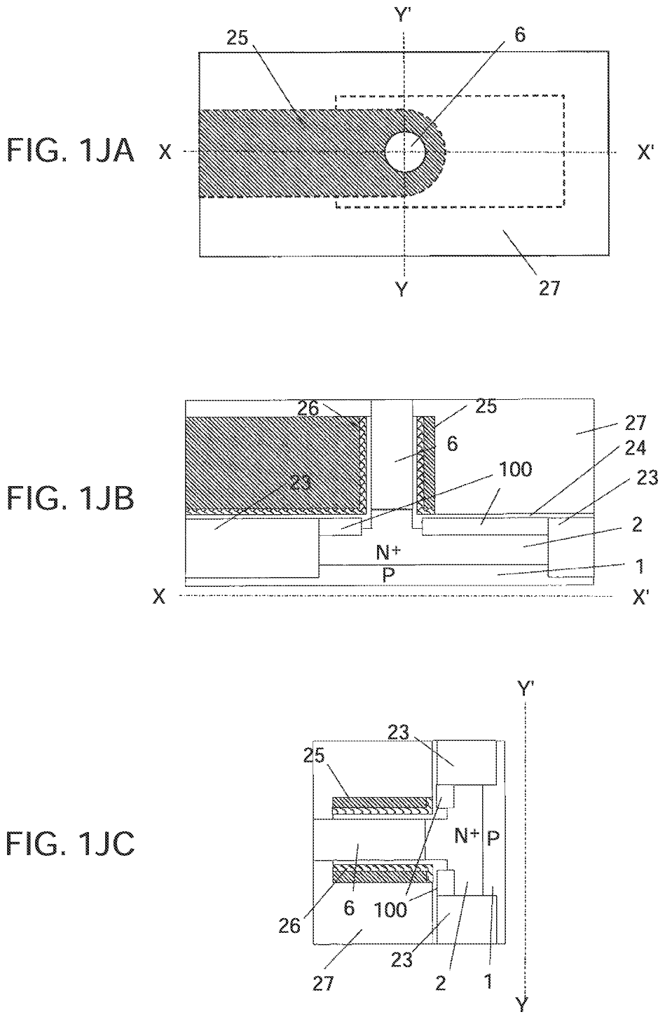

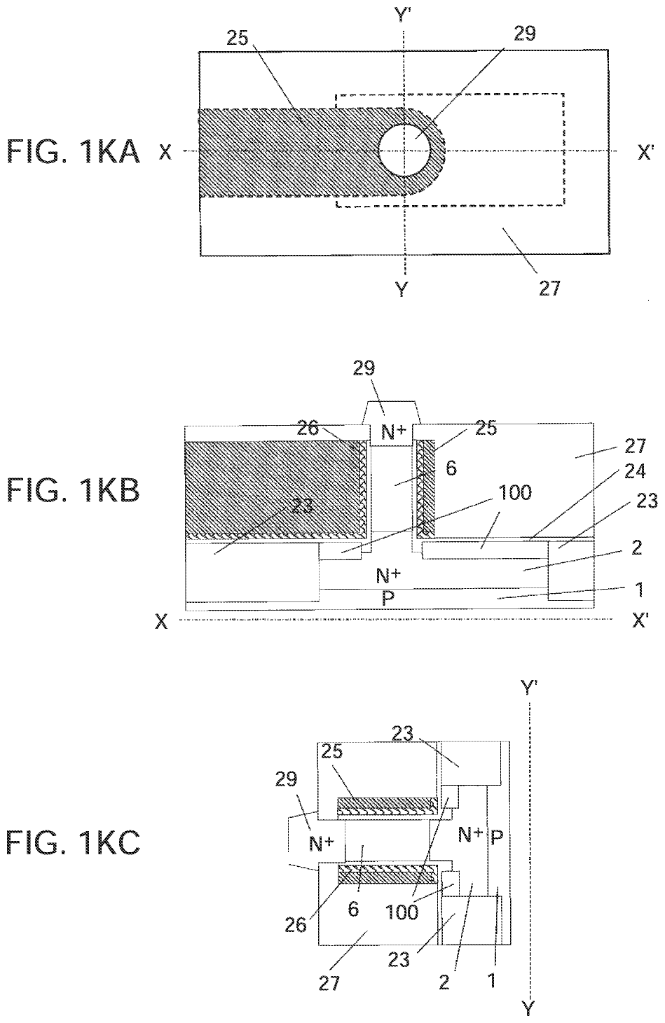

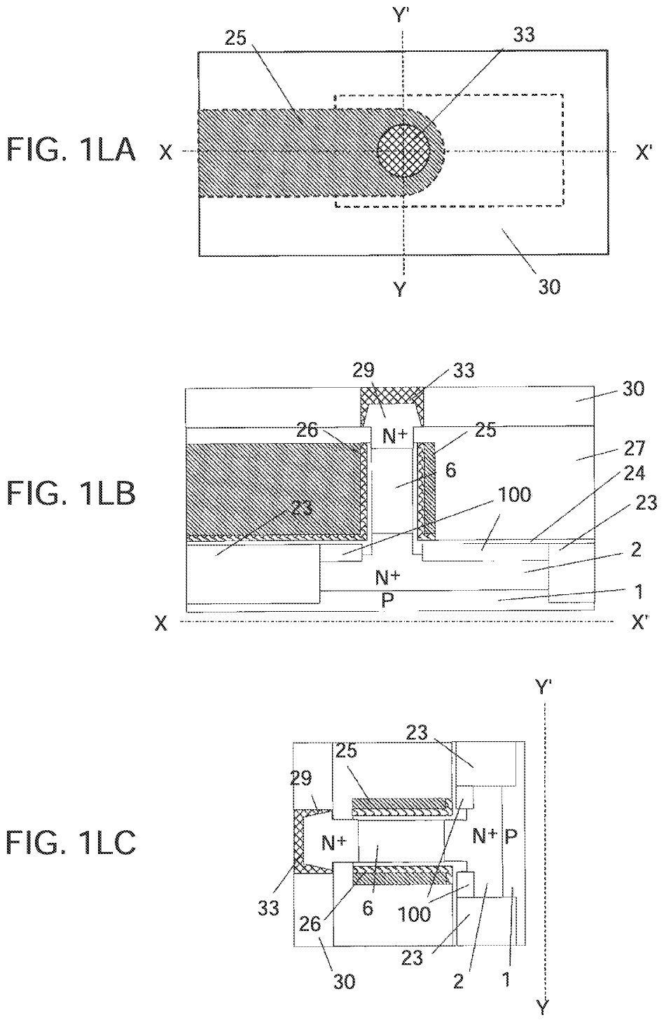

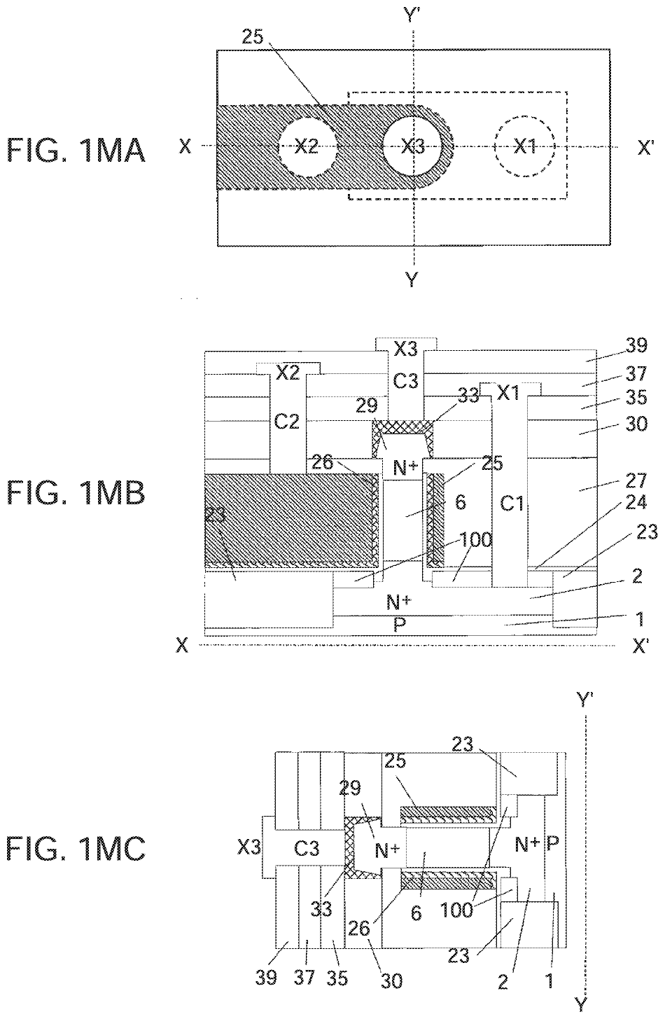

Hereinafter, using an example of an N-type transistor, a manufacturing method of an SGT according to a first embodiment of the present invention will be described with reference to FIGS. 1AA to 1MC. In each diagram, A represents a plan view, B represents a sectional structural diagram taken along an X-X′ line in A, and C represents a sectional structural diagram taken along a Y-Y′ line in A.

An N⁺ layer 2 (an example of the “first impurity region” according to the scope of claims) and an i layer 6 (an example of the “semiconductor pillar” according to the scope of claims) are formed by an epitaxial crystal growth method on a P layer 1 (an example of the “substrate” according to the scope of claims) and, as shown in FIGS. 1AA to 1AC, for example, a mask material layer 7 (an example of the “second mask material layer” according to the scope of claims) made of SiN, a mask semiconductor layer 8 made of silicon-germanium (SiGe), and a mask semiconductor layer 9 made of SiO₂ are sequentially deposited. Note that the i layer 6 may be formed of N-type or P-type Si containing a small amount of donor impurity atoms or acceptor impurity atoms.

Next, using a resist layer (not illustrated) with a circular or rectangular shape in a plan view formed by a lithographic method as a mask, the mask semiconductor layer 9 is etched. Using the SiO₂ mask semiconductor layer 9 with a circular or rectangular shape as an etching mask, the mask semiconductor layer 9 with a circular or rectangular shape is formed by etching by, for example, RIE (Reactive Ion Etching). Next, using the mask semiconductor layer 9 with a circular or rectangular shape as a mask, the SiGe mask semiconductor layer 8 with a circular or rectangular shape is formed as shown in FIGS. 1BA to 1BC by etching the SiGe mask semiconductor layer 8 by, for example, RIE method. The SiO₂ mask semiconductor layer 9 with a circular or rectangular shape described above may be removed before etching the SiGe mask semiconductor layer 8 or may be left.

Next, using the SiO₂ mask semiconductor layer 9 and the SiGe mask semiconductor layer 8 described above as etching masks, etching is sequentially performed by, for example, RIE to form the mask material layer 7 and the i layer 6 with a circular or rectangular shape as shown in FIGS. 1CA to 100 and the mask semiconductor layer 9 and the SiGe layer 8 left on the mask material layer 7 are removed. In doing so, the SiO₂ mask semiconductor layer 9 and the SiGe mask semiconductor layer 8 may be left as-is instead of being removed.

Next, as shown in FIGS. 1DA to 1DC, a mask material layer 21 (an example of the “first mask material layer” according to the scope of claims) with oxidation resistance such as a SiN layer is formed by an ALD method so as to cover the entire stack.

Next, using a resist layer (not illustrated) formed by a lithographic method as a mask, an operation region and an insulation region of a transistor are patterned and the mask material layer 21 and the substrate which are present in the insulation region that constitutes a resist opening portion are etched by an RIE method. Next, after removing the photoresist, a SiO₂ layer 23 that has a thickness greater than at least a depth of the etching is formed by an FCVD method so as to cover the entire stack. Next, the entire stack is polished by a CMP method so that an upper surface position of the SiO₂ layer 23 equals an upper surface position of the mask material layer 7 present on the semiconductor pillar and, subsequently, as shown in FIGS. 1EA to 1EC, the SiO₂ layer 23 is etched back so that the upper surface position of the SiO₂ layer 23 equals an upper surface position of the mask material layer 21 to form an inter-element insulation region.

Next, as shown in FIGS. 1FA to 1FC, the mask material layer 21 is etched by an RIE method to leave the mask material layer 21 on a side wall of the semiconductor pillar and to expose the mask material layer 7 in the top part of the semiconductor pillar and the surface of the substrate in a plan view.

Next, as shown in FIGS. 1GA to 1GC, an oxide film 100 (an example of the “first insulation layer” according to the scope of claims) is thermally or chemically formed on the surface of the substrate.

Next, as shown in FIGS. 1HA to 1HC, the mask material layer 21 is subjected to isotropic etching and the mask material layer 21 left on the side wall of the semiconductor pillar is removed.

Next, the entire stack is coated by a HfO₂ layer 24 (an example of the “gate insulating layer” according to the scope of claims), a TiN layer 26 (an example of the “gate conductor layer” according to the scope of claims), and a W layer 25 (an example of the “gate conductor layer” according to the scope of claims), and the entire stack is polished by a CMP method so that an upper surface position of the W layer 25 equals the upper surface position of the mask material layer 7 present on the semiconductor pillar. As shown in FIGS. 1IA to 1IC, the W layer 25 having been planarized by an RIE method is etched back so as to be separated from the top of the semiconductor pillar 6 and, in doing so, the exposed HfO₂ layer 24 and the TiN layer 26 are removed by isotropic etching.

Next, using a resist layer (not illustrated) formed by a lithographic method as a mask, a gate conductor layer is patterned by etching the W layer 25 and the TiN layer 26 by an RIE method and, subsequently, the entire stack is coated by an interlayer insulator film 27 (an example of the “second insulation layer” according to the scope of claims) and, as shown in FIGS. 1JA to 1JC, the entire stack is polished by a CMP method so that an upper surface position of the entire stack equals the upper surface position of the semiconductor pillar.

Next, the top part of the semiconductor pillar 6 exposed on the surface is etched by recess etching so that the surface of the top part is recessed with respect to the surface of the interlayer insulator film 27 in a plan view and, as shown in FIGS. 1KA to 1KC, an N⁺ layer 29 (an example of the “second impurity region” according to the scope of claims) containing donor impurities is formed on the exposed top part of the semiconductor pillar 6 by a selective epitaxial crystal growth method.

Next, the entire stack is coated by an interlayer insulator film 30 and polished and planarized by a CMP method. Next, using a resist layer (not illustrated) formed by a lithographic method as a mask, the interlayer insulator film 30 in an upper part of the N⁺ layer 29 is etched and removed by an RIE method. Next, the entire stack is coated with a TiN layer (not illustrated) and a W layer 33 and, as shown in FIGS. 1LA to 1LC, the entire stack is polished by a CMP method so that an upper part of the interlayer insulator film 30 is exposed.

Note that the present step may be performed by a method of coating with the TiN layer (not illustrated) and the W layer 33 before the SiO₂ layer 30, leaving the TiN layer and the W layer so as to come into contact with at least a part of the N⁺ layer 29 by a lithographic method and RIE (Reactive Ion Etching), coating the entire stack by the SiO₂ layer 30 by a CVD method, and polishing the entire stack by a CMP method until the surface of the W layer is exposed.

Next, a SiO₂ layer 35 with a flat upper surface is formed so as to cover the entire stack. A source or a drain wiring metal layer X1 is formed via a contact hole C1 formed on the N⁺ layer 2. Next, a SiO₂ layer 37 with a flat upper surface is formed so as to cover the entire stack. A word wiring metal layer X2 is formed via a contact hole C2 formed on the W layer 25. Next, a SiO₂ layer 39 with a flat upper surface is formed so as to cover the entire stack. As shown in FIGS. 1MA to 1MC, a source or a drain wiring metal layer X3 is formed via a contact hole C3 formed on the W layer 33.

Accordingly, the N-type transistor of an SGT is completed.

Note that due to a thermal process after formation of the N⁺ layer 2 shown in FIGS. 1EA to 1EC and the N⁺ layer 29 shown in FIGS. 1KA to 1KC, donor impurities are diffused and a donor impurity region is also formed inside the semiconductor pillar 6. When each layer is formed as a P⁺ layer, acceptor impurities are diffused and an acceptor impurity region is also formed inside the semiconductor pillar 6 in a similar manner.

When attempting to increase operation speed or reduce power consumption in a circuit using an SGT, a reduction in parasitic capacitance is performed by methods such as reducing a channel length and reducing capacitance between a gate and a substrate in a transistor. An attempt to achieve both objectives results in the following problems.

### Problem 1.

Reducing the channel length of a transistor causes a short channel effect to become prominent and a variation in channel length induces a variation in transistor characteristics and a decline in withstand-voltage of the transistor.

### Problem 2.

While the insulator film between the gate and the substrate directly under a gate electrode may be thickly formed when reducing the parasitic capacitance between the gate and the substrate in an SGT structure, such a formation method causes a variation in gate length and induces operational failures.

The manufacturing method according to the first embodiment provides the following features with respect to the problems described above.
1. The mask material layers 7 and 21 which respectively have oxidation resistance can be left in the top part and on the side wall of the semiconductor pillar 6 prior to the formation of the gate insulating layer and the gate electrode, the insulator film 100 can be selectively formed with good controllability by a thermal or chemical oxidation method in a region where the surface of the N⁺ layer 2 is exposed outside of the mask material layers 7 and 21 in a plan view, and a gate electrode to be formed in an upper part of the insulator film 100 can be formed so that a lower end of the gate electrode is arranged at a desired position without variation.
2. While an example in which the present invention is applied to an N-type transistor has been described in the present embodiment, a P-type transistor can be formed by forming the N⁺ layer 2 shown in FIGS. 1AA to 1AC and the N⁺ layer 29 shown in FIGS. 1KA to 1KC and subsequent drawings with a P⁺ layer.
3. In addition, since both an N-type transistor and a P-type transistor can be readily created using the present invention, the present invention can also be used in memories such as an SRAM and a Flash memory in addition to logic memories. Furthermore, the semiconductor pillar 6 with a circular shape in a plan view is formed in the present embodiment. As the shape of a part of or the entire present semiconductor pillar in a plan view, a circle, an ellipse, a shape elongated in one direction, and the like can be readily formed. In addition, even in a logic circuit region which is formed separated from the SRAM region, a mixture of semiconductor pillars with different shapes in a plan view can be formed in the logic circuit region in accordance with logic circuit design. Accordingly, a microprocessor circuit with high performance and low power consumption can be realized.

### Second Embodiment

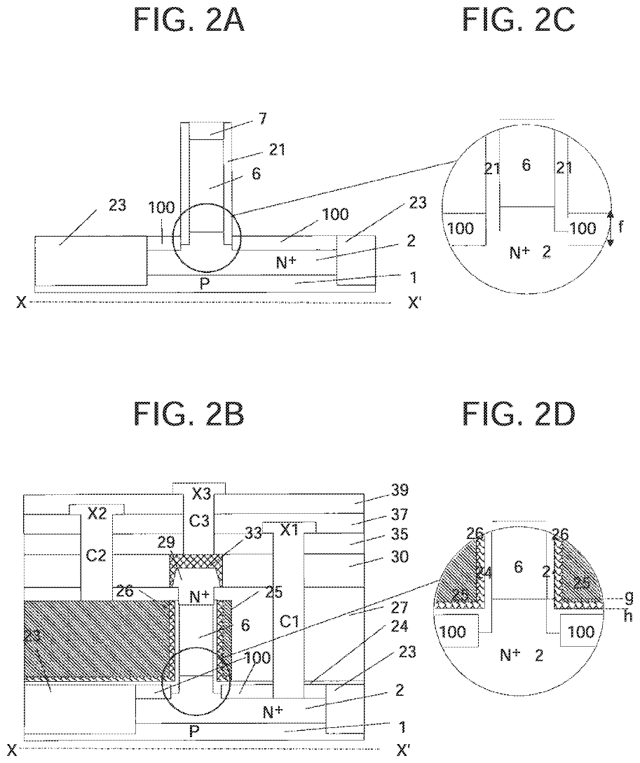

Hereinafter, using an example of an N-type transistor, a manufacturing method of an SGT according to a second embodiment of the present invention will be described with reference to FIGS. 2A to 2D. A represents a sectional structural diagram taken along an X-X′ line in FIGS. 1GA to 1GC according to the first embodiment, C represents an enlarged view of main parts related to the present embodiment in A, B represents a sectional structural diagram taken along an X-X′ line in FIGS. 1MA to 1MC according to the first embodiment, and D represents an enlarged view of main parts related to the present embodiment in B.

When forming the insulator film 100 shown in FIG. 2A so that an upper end position g of the N⁺ layer 2 does not become lower than an upper end position of the HfO₂ layer 24 or, in other words, a lower end position h of the gate electrode 25 as shown in FIG. 2D, a film thickness f of the insulator film 100 is set as shown in FIG. 2C.

The present embodiment provides the following features.
1. By suitably setting the film thickness of the insulator film 100 as shown in FIGS. 2A to 2D, the W gate electrode layer 25, the TiN layer 26, and the N⁺ layer 2 sufficiently overlap with each other in the vertical direction and failures and variation in characteristics can be suppressed.
2. In addition, since the insulator film 100 can be formed to be sufficiently thicker than the film thickness of the HfO₂ gate insulating layer 24, a parasitic capacitance between the substrate and the gate electrode can be reduced and a contribution can be made toward increasing operation speed and reducing power consumption in products using the present structure.

### Third Embodiment

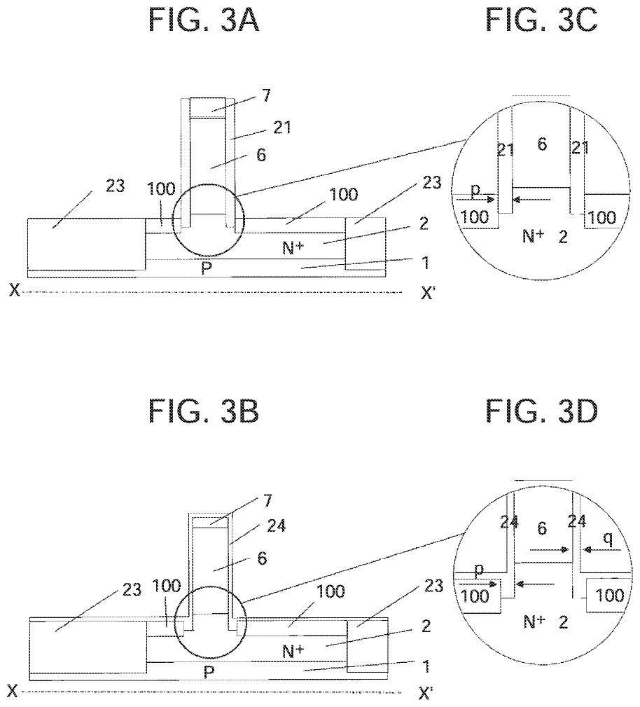

Hereinafter, using an example of an N-type transistor, a manufacturing method of an SGT according to a third embodiment of the present invention will be described with reference to FIGS. 3A to 3D. A represents a sectional structural diagram taken along an X-X′ line in FIGS. 1GA to 1GC according to the first embodiment, C represents an enlarged view of main parts related to the present embodiment in A, B represents a sectional structural diagram taken along an X-X′ line in a state where the HfO₂ gate insulating layer 24 has been formed after the state shown in FIGS. 1HA to 1HC according to the first embodiment, and D represents an enlarged view of main parts related to the present embodiment in B.

The mask material layer 21 is left on the side wall of the semiconductor pillar 6 shown in FIG. 3A by anisotropic etching, and in a next step of forming the insulator film 100, as shown in FIG. 3C, a film thickness p of the mask material layer 21 which is left on the side wall in a lower part of the semiconductor pillar 6 is approximately equal to a film thickness immediately after formation of the mask material layer 21 shown in FIGS. 1DA to 1DC according to the first embodiment. Next, while the left mask material layer 21 is removed by isotropic etching, in doing so, a depression is created between the lower part of the semiconductor pillar 6 and the insulator film 100 and a width of the depression is equal to p described above. Next, while the HfO₂ gate insulating layer 24 is formed as shown in FIG. 3B, since the depression is filled with a film thickness q of the HfO₂ gate insulating layer 24 as shown in FIG. 3D, the film thickness p of the mask material layer 21 is desirably set thinner than a film thickness that is twice the film thickness q of the HfO₂ gate oxide film layer 24.

The present embodiment provides the following features.

By filling a depression that is locally present between the lower part of the semiconductor pillar 6 and the insulator film 100 with the HfO₂ gate oxide film layer 24, the W gate electrode layer 25 and the TiN layer 26 penetrate into the depression to prevent the parasitic capacitance between the gate electrode and the semiconductor pillar from being locally increased and a contribution can be made toward increasing operation speed and reducing power consumption in products using the present structure.

### Fourth Embodiment

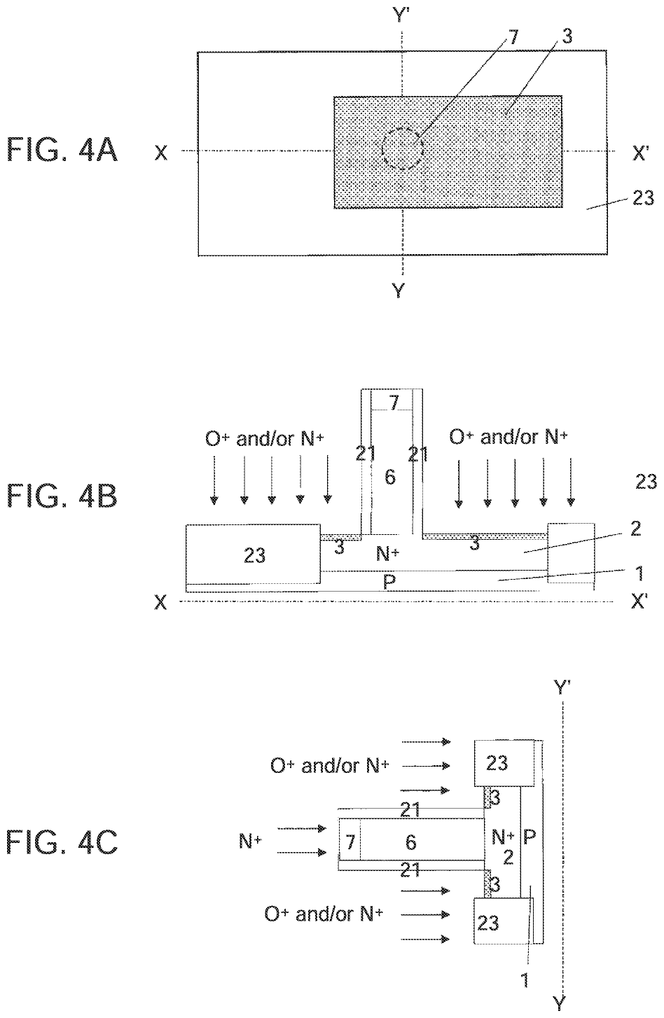

Hereinafter, using an example of an N-type transistor, a manufacturing method of an SGT according to a fourth embodiment of the present invention will be described with reference to FIGS. 4A to 4C. FIGS. 4A to 4C shows a state where the fourth embodiment is implemented after completing the step shown in FIGS. 1FA to 1FC according to the first embodiment, in which A represents a plan view, B represents a sectional structural diagram taken along an X-X′ line in A, and C represents a sectional structural diagram taken along a Y-Y′ line in A.

As shown in FIGS. 4A to 4C, the mask material layer 21 is etched by an RIE method to leave the mask material layer 21 on a side wall of the semiconductor pillar and to expose the mask material layer 7 in the top part of the semiconductor pillar and the surface of the substrate in a plan view, and one of or both oxygen ions and impurities of a same conductivity type as the impurity region of the N⁺ layer 2 are implanted to the entire exposed surface of the substrate by an ion implantation method to form an impurity region layer 3.

Subsequent steps are the same as those subsequent to FIGS. 1GA to 1GC in the first embodiment.

The present embodiment provides the following features.

By implanting oxygen or impurities of a same conductivity type to a surface of the substrate to be formed before thermally or chemically forming the oxide film 100, an oxide film growth rate can be significantly increased and an oxide film can be formed at low temperature and within a short period of time. A greater effect can be produced if the oxidation is performed by an ozone thermal oxidation method. Accordingly, impurity diffusion due to heat can be suppressed and a characteristic variation, a withstand-voltage failure, and the like can be suppressed.

### Fifth Embodiment

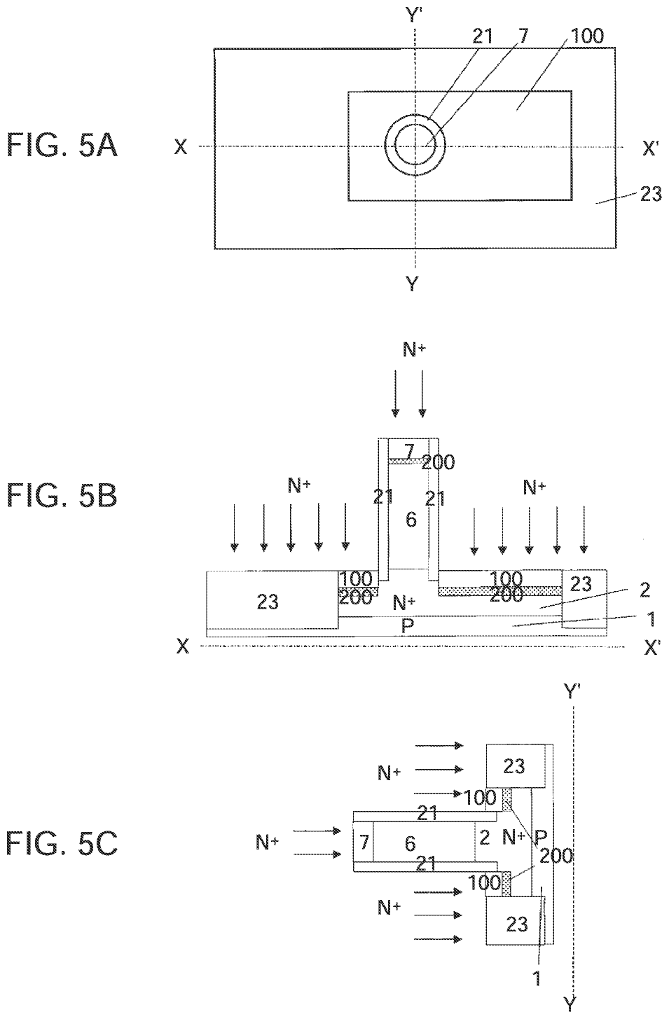

Hereinafter, using an example of an N-type transistor, a manufacturing method of an SGT according to a fifth embodiment of the present invention will be described with reference to FIGS. 5A to 5C. FIGS. 5A to 5C shows a state where the fifth embodiment is implemented after completing the step shown in FIGS. 1GA to 1GC according to the first embodiment, in which A represents a plan view, B represents a sectional structural diagram taken along an X-X′ line in A, and C represents a sectional structural diagram taken along a Y-Y′ line in A.

As shown in FIGS. 5A to 5C, after thermally or chemically forming the oxide film 100 on the surface of the substrate, impurities of a same conductivity type as the impurity region of the N⁺ layer 2 are implanted by an ion implantation method to an entire region below the first insulation layer with energy that enables a sufficient amount of the impurities to be implanted to form an impurity region 200.

Subsequent steps are the same as those subsequent to FIGS. 1HA to 1HC in the first embodiment.

The present embodiment provides the following features.

When thermally or chemically forming the oxide film 100 on the surface of the substrate, an impurity concentration of the N⁺ layer 2 directly below the oxide film 100 drops and electrical resistance rises. In order to prevent the drop in impurity concentration and the rise in electrical resistance, impurities of a same conductivity type as the N⁺ impurity region 2 are implanted after forming the insulator film 100 to compensate for the drop in impurity concentration and to suppress an increase in electrical resistance. In doing so, while there is a possibility that the impurities are also implanted to the top part of the semiconductor pillar 6 through the mask material layer 7, since the top part of the semiconductor pillar 6 is to be removed by recess etching when forming the N⁺ layer 29 containing donor impurities, the implantation of the impurities to the top part of the semiconductor pillar 6 is noninfluential.

### Sixth, Seventh, and Eighth Embodiments

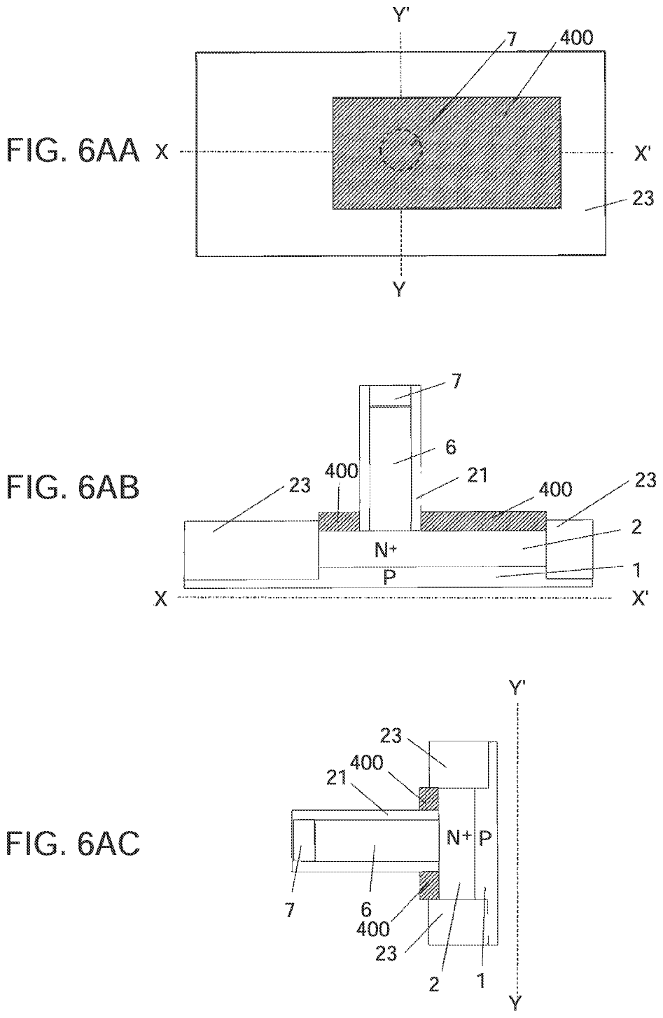

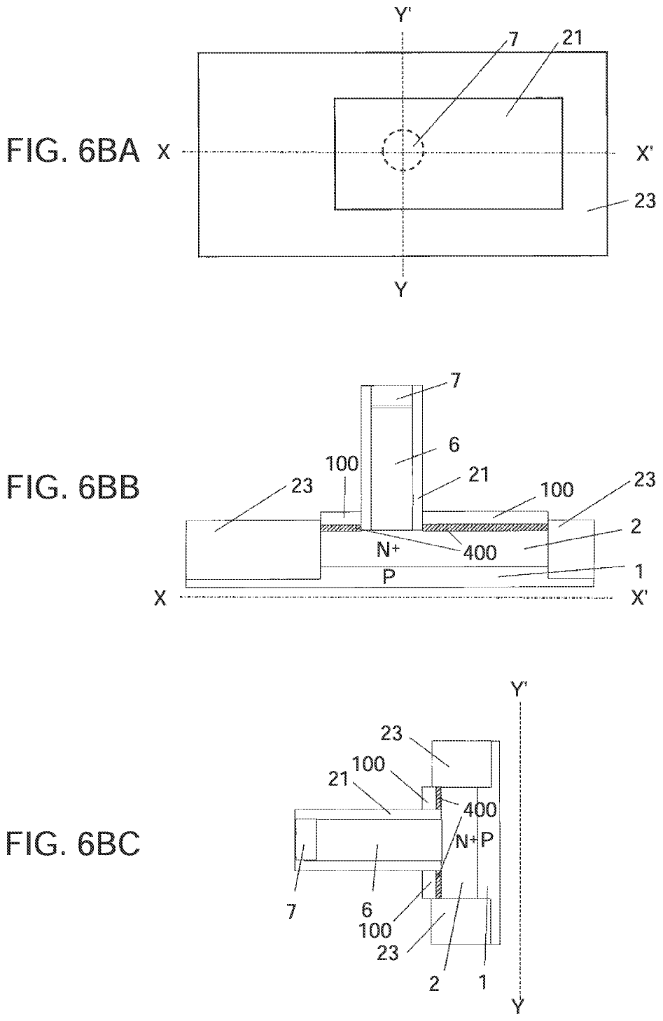

Hereinafter, using an example of an N-type transistor, a manufacturing method of an SGT according to sixth, seventh, and eighth embodiments of the present invention will be described with reference to FIGS. 6AA to 6AC and 6BA to 6BC. In FIGS. 6AA to 6AC and 6BA to 6BC, A represents a plan view, B represents a sectional structural diagram taken along an X-X′ line in A, and C represents a sectional structural diagram taken along a Y-Y′ line in A.

As shown in FIGS. 6AA to 6AC, after the step shown in FIGS. 1FA to 1FC according to the first embodiment, a semiconductor layer 400 (an example of the “semiconductor layer” according to the scope of claims) is formed on the exposed surface of the substrate by selective epitaxial growth.

Next, as shown in FIGS. 6BA to 6BC, the entire semiconductor layer 400 is thermally and chemically oxidized to form the insulator film 100. In doing so, by using a material that is greater in terms of an oxide film growth rate than that of the N⁺ impurity region 2 for the semiconductor layer 400, the oxide film can be formed at low temperature and within a short period of time.

Furthermore, if the semiconductor layer 400 is a semiconductor layer doped with impurities of a same conductivity type as the N⁺ impurity region 2, the oxide film growth rate can be further increased and the oxide film can be formed at a lower temperature and within a shorter period of time.

Subsequent steps are the same as those subsequent to FIGS. 1IA to 1IC in the first embodiment.

The present embodiment provides the following features.
1. Since a semiconductor layer subjected to selective epitaxial growth is oxidized as shown in FIGS. 6BA to 6BC, the upper end of the insulator film 100 to be a lower end position of the gate electrode can be set to a position sufficient higher than the upper end of the N⁺ impurity region 2 and a risk of creating an offset structure being one of the factors causing a significant decline in transistor characteristics is minimized.
2. Since the N⁺ impurity region 2 can be made hardly oxidizable by increasing an oxidation rate of the semiconductor layer 400 when forming the insulator film 100, an impurity concentration of the N⁺ impurity region 2 is unaffected and a contribution can be made toward increasing operation speed and reducing power consumption in products using the present structure without causing a variation in transistor characteristics and a drop in drive capability.

### Ninth Embodiment

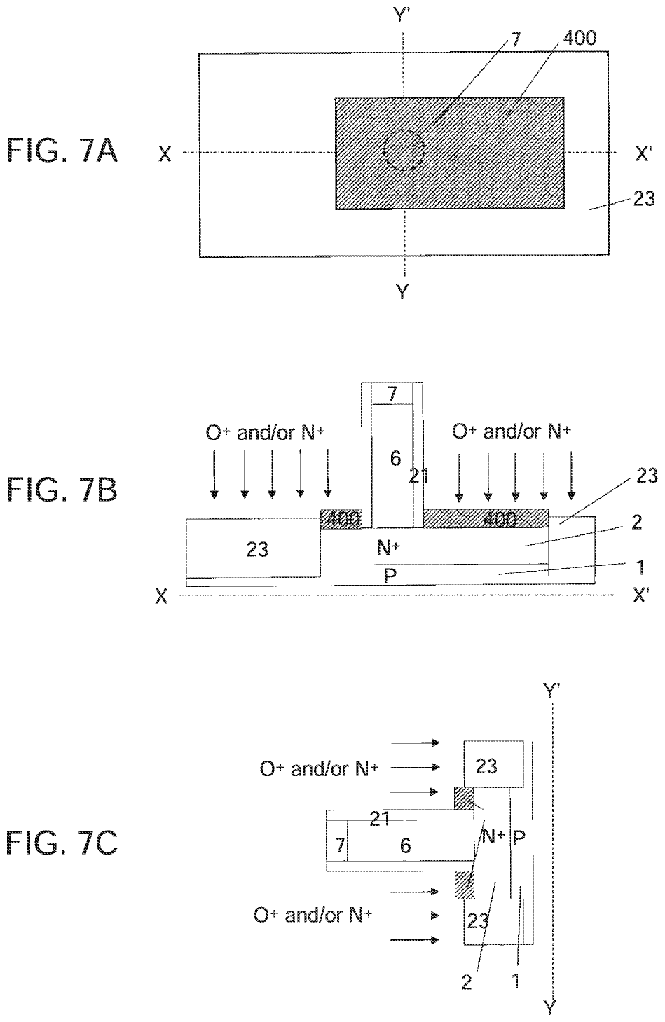

Hereinafter, using an example of an N-type transistor, a manufacturing method of an SGT according to a ninth embodiment of the present invention will be described with reference to FIGS. 7A to 7C. In FIGS. 7A to 7C, A represents a plan view, B represents a sectional structural diagram taken along an X-X′ line in A, and C represents a sectional structural diagram taken along a Y-Y′ line in A.

After selectively epitaxially growing the semiconductor layer 400 in the step shown in FIGS. 6AA to 6AC according to the seventh embodiment, one of or both oxygen ions and impurities of a same conductivity type as the impurity region of the N⁺ layer 2 are implanted as shown in FIGS. 7A to 7C to the entire semiconductor layer 400 by an ion implantation method with energy that enables the oxygen ions and the impurities to remain inside the semiconductor layer 400.

Steps subsequent to FIGS. 6BA to 6BC are the same as those subsequent to FIGS. 1HA to 1HC in the first embodiment.

The present embodiment provides the following features.
1. By implanting at least one of oxygen ions and impurities of a same conductivity type as the impurity region of the N⁺ layer 2 by implanting ion to the semiconductor layer 400, the semiconductor layer 400 can be oxidized at low temperature and within a short period of time. A greater effect can be produced if the oxidation is performed by an ozone thermal oxidation method. Accordingly, impurity diffusion due to heat can be suppressed and a characteristic variation, a withstand-voltage failure, and the like can be suppressed.
2. Since the oxide film growth rate of the semiconductor layer 400 can be further increased using the N⁺ impurity region 2 and oxidation of the N⁺ impurity region 2 can be suppressed by implanting at least one of oxygen ions and impurities of a same conductivity type as the impurity region of the N⁺ layer 2 by implanting ion to the semiconductor layer 400, an impurity concentration of the N⁺ impurity region 2 is unaffected and a contribution can be made toward increasing operation speed and reducing power consumption in products using the present structure without causing a variation in transistor characteristics and a drop in drive capability.

### Tenth Embodiment

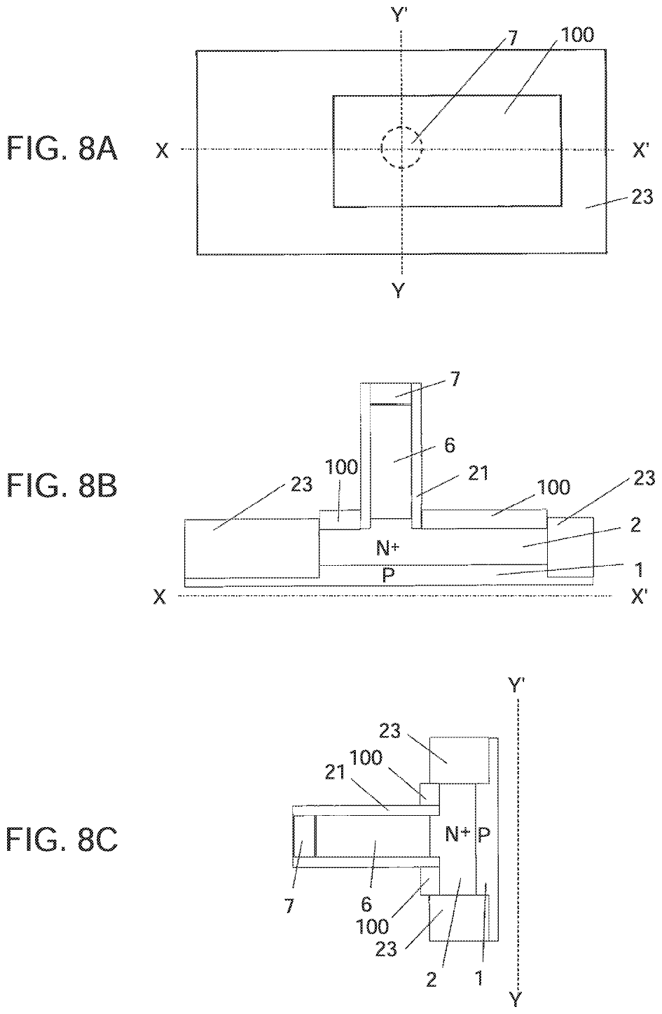

Hereinafter, using an example of an N-type transistor, a manufacturing method of an SGT according to a tenth embodiment of the present invention will be described with reference to FIGS. 8A to 8C. In FIGS. 8A to 8C, A represents a plan view, B represents a sectional structural diagram taken along an X-X′ line in A, and C represents a sectional structural diagram taken along a Y-Y′ line in A.

When thermally oxidizing the semiconductor layer 400 having been subjected to selective epitaxial growth in the step shown in FIGS. 6BA to 6BC according to the seventh embodiment, as shown in FIGS. 8A to 8C, the film thickness of the semiconductor layer 400 is set such that oxidation is performed under a condition which changes the entire semiconductor layer 400 into the insulator film 100 and, as a result, the film thickness of the insulator film 100 assumes a desired film thickness.

Subsequent steps are the same as those subsequent to FIGS. 1HA to 1HC in the first embodiment.

The present embodiment provides the following features.

By utilizing a difference in oxide film growth rates between the semiconductor layer 400 and the N⁺ impurity region 2, the insulator film 100 can be formed by only oxidizing the semiconductor layer 400 and, as a result, the insulator film 100 can be formed with good controllability of a film thickness of the insulator film 100. Accordingly, a variation in transistor characteristics can be further suppressed.

### Eleventh Embodiment

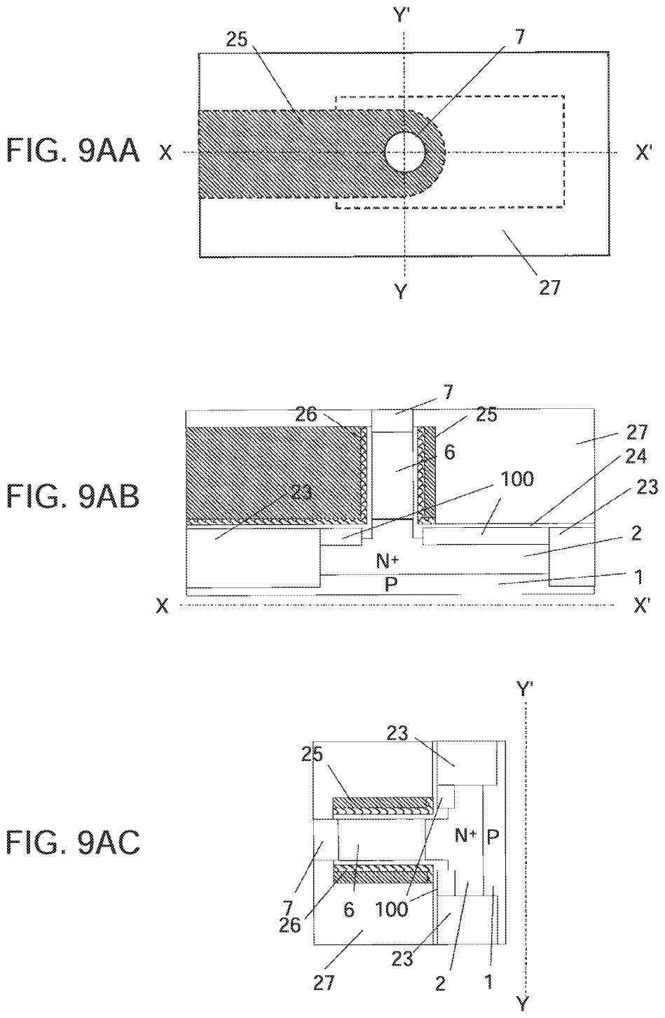

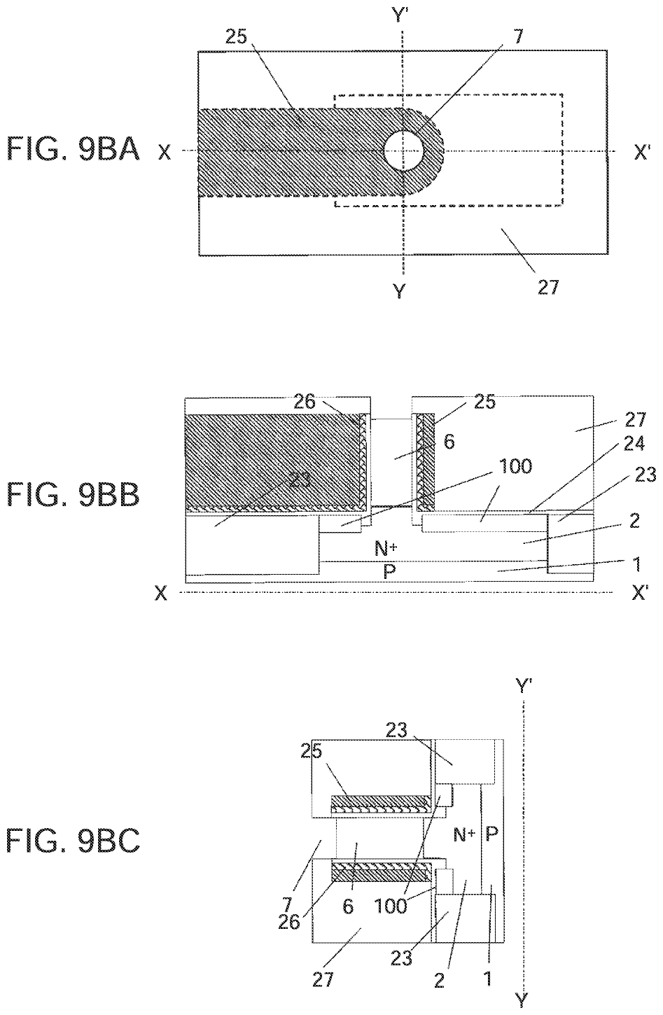

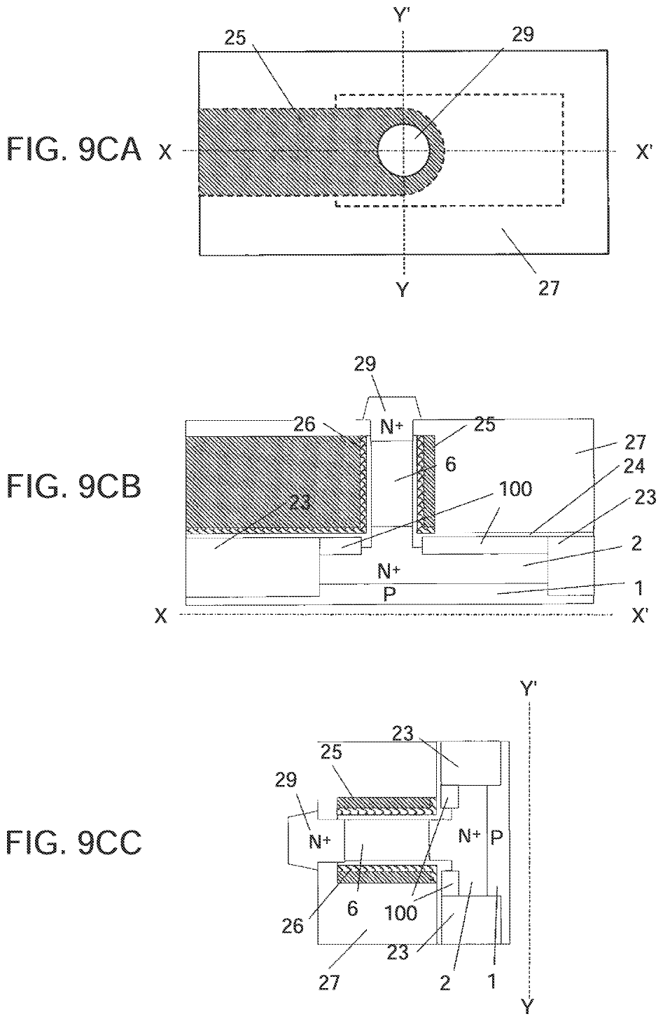

Hereinafter, an N-type transistor will be described as an example of a manufacturing method of an SGT according to an eleventh embodiment of the present invention with reference to FIGS. 9AA to 9AC, 9BA to 9BC, and 9CA to 9CC. In FIGS. 9AA to 9AC, 9BA to 9BC, and 9CA to 9CC, A represents a plan view, B represents a sectional structural diagram taken along an X-X′ line in A, and C represents a sectional structural diagram taken along a Y-Y′ line in A.

FIGS. 9A to 9C corresponds to FIGS. 1J to 1JC in the first embodiment, in which after patterning a gate conductor layer, the entire gate conductor layer is coated by the interlayer insulator film 27, and the entire interlayer insulator film 27 is polished by a CMP method so that an upper surface position thereof equals an upper surface position of the SiN mask material layer 7. A film thickness at which the SiN mask material layer 7 is to be formed is set in FIGS. 1A to 1AC so as to use the SiN mask material layer 7 in the present step as a stopper of polishing by the CMP method.

Next, as shown in FIGS. 9BA to 9BC, the left SiN mask material layer 7 is removed by isotropic etching. Next, as shown in FIGS. 9CA to 9CC, the N⁺ layer 29 containing donor impurities is formed on the exposed top part of the semiconductor pillar 6 by a selective epitaxial crystal growth method.

In this manner, the SiN mask material layer 7 is not only used as a mask material layer for forming the semiconductor pillar 6 but also used as a film for determining a formation position of the N⁺ impurity layer 29 in the top part of the semiconductor pillar 6. Therefore, when the SiN mask material layer 7 is formed in FIGS. 1A to 1AC, the film thickness of the SiN mask material layer 7 is set to a sufficient thickness for the SiN mask material layer 7 to function as a stopper of polishing by the CMP method in FIGS. 9A to 9C.

Subsequent steps are the same as those subsequent to FIGS. 1LA to 1LC in the first embodiment.

The present embodiment provides the following features.

By using the SiN mask material layer 7 not only as a mask material layer for forming the semiconductor pillar 6 but also as a stopper when polishing the interlayer insulator film 27 by a CMP method, a variation in the formation position of the N⁺ impurity layer 29 in the top part of the semiconductor pillar 6 is suppressed and, as a result, a variation in the length of the semiconductor pillar 6 which corresponds to a channel length of the SGT can be suppressed. Accordingly, a variation in transistor characteristics can be suppressed.

By performing the eleventh embodiment as described above instead of performing the steps shown in FIGS. 1IA to 1KC according to the first embodiment, variation can be suppressed with respect to both a gate length and a channel length of an SGT. In other words, a variation in gate length can be suppressed in the first embodiment by suppressing a variation in the position of a lower end of a gate electrode as described above, and a variation in channel length can be suppressed in the eleventh embodiment by suppressing a variation in the position of the top part of the semiconductor pillar 6 which corresponds to the channel length.

### Twelfth Embodiment

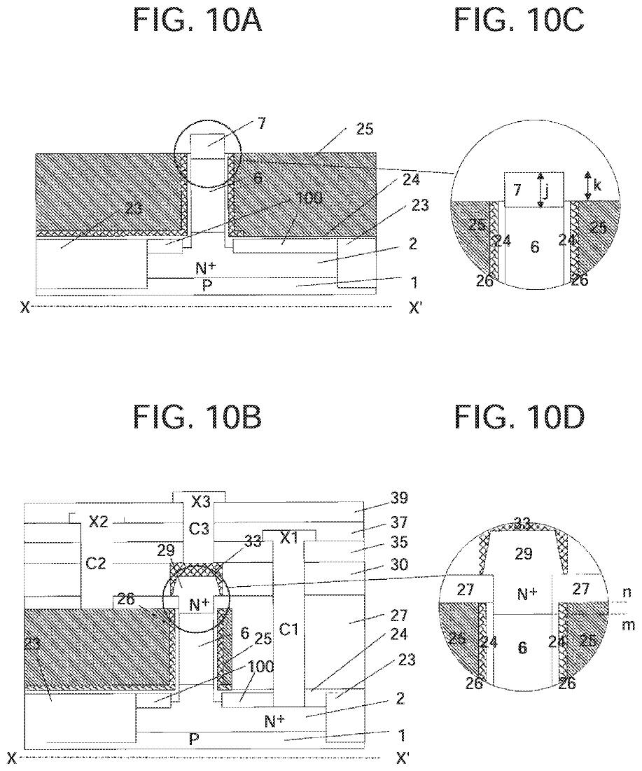

Hereinafter, using an example of an N-type transistor, a manufacturing method of an SGT according to a twelfth embodiment of the present invention will be described with reference to FIGS. 10A to 10D. A represents a sectional structural diagram taken along an X-X′ line in FIGS. 9A to 9C according to the eleventh embodiment, C represents an enlarged view of main parts related to the present embodiment in A, B represents a sectional structural diagram taken along an X-X′ line in FIGS. 1MA to 1MC according to the first embodiment, and D represents an enlarged view of main parts related to the present embodiment in B.

In a step of etching back the gate electrode 25 shown in FIGS. 10AA to 10AD by an RIE method so that a lower end position n of the interlayer insulator film 27 or, in other words, an upper end position n of the gate electrode 25 does not become lower than a lower end position m of the impurity region 29 as shown in FIG. 10D, a film thickness j of the mask material layer 7 present on the semiconductor pillar 6 is set so that the film thickness j becomes greater than a film thickness k at which the W gate electrode layer 25 and the TiN layer 26 are etched as shown in FIG. 100.

The present embodiment provides the following features.
1. By suitably setting the film thickness of the mask material layer 7 as shown in FIGS. 10A to 10D, the W gate electrode layer 25, the TiN layer (not illustrated), and the N⁺ impurity layer 29 sufficiently overlap with each other in the vertical direction, and since an electric short-circuit between the gate electrode and the N⁺ impurity layer 29 can be suppressed, failures and variation in characteristics can be suppressed.
2. In addition, since the film thickness of the interlayer insulator film 27 on the gate electrode which is determined by the film thickness j of the mask material layer 7 and the film thickness k at which the gate electrode is etched can be formed to be sufficiently thicker than the film thickness of the HfO₂ insulating layer 24, a parasitic capacitance between the N⁺ impurity region layer 29 and the gate electrode 25 can be reduced and a contribution can be made toward increasing operation speed and reducing power consumption in products using the present structure.

### Thirteenth Embodiment

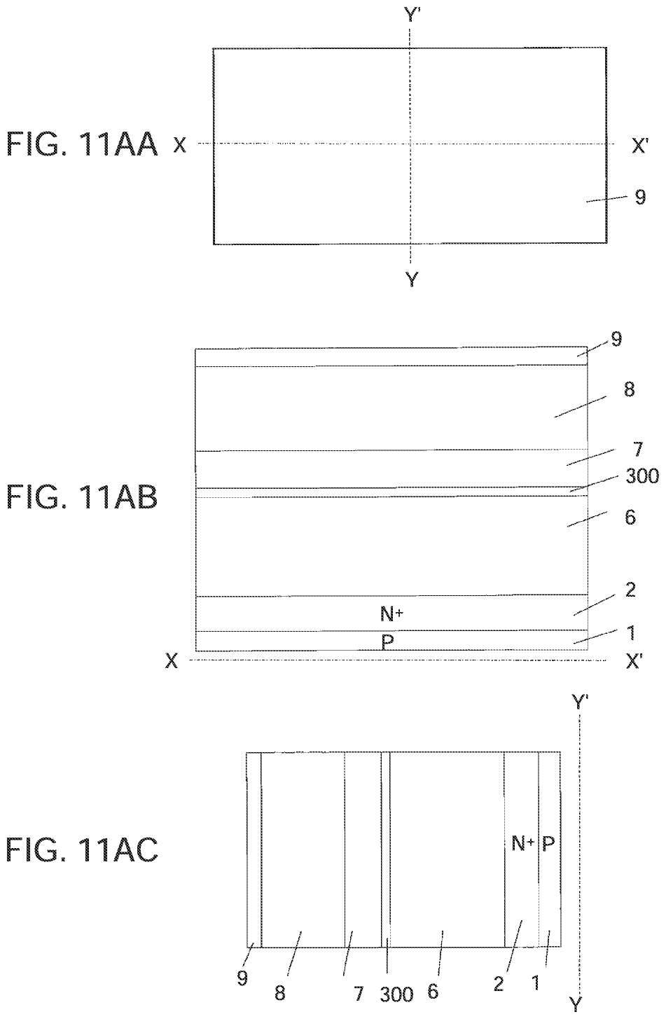

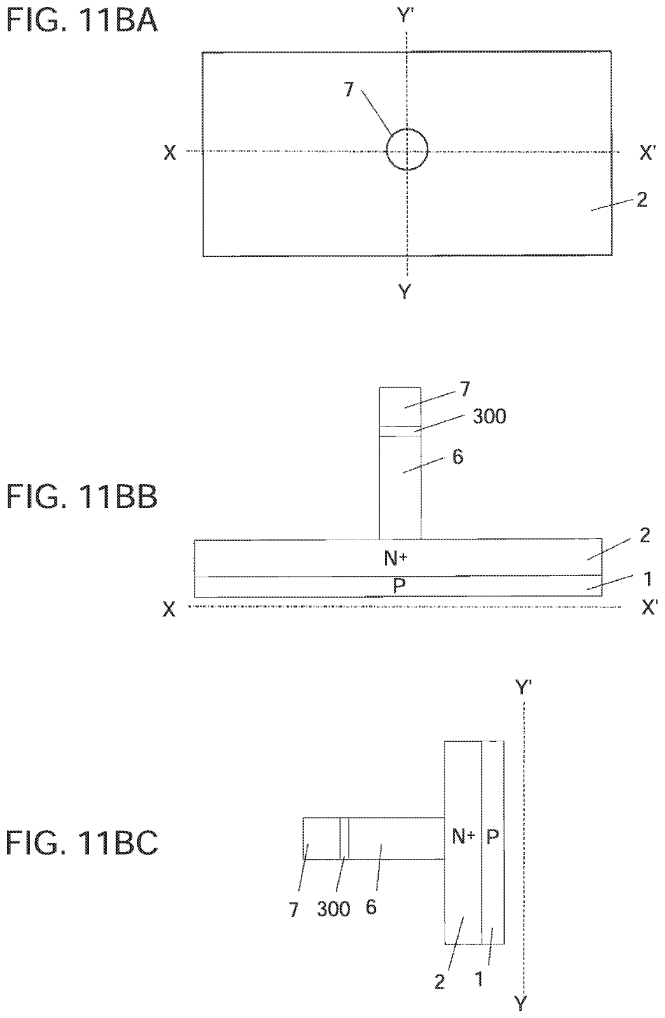

Hereinafter, using an example of an N-type transistor, a manufacturing method of an SGT according to a thirteenth embodiment of the present invention will be described with reference to FIGS. 11AA to 11AC and 11BA to 11BC. In FIGS. 11AA to 11AC and 11BA to 11BC, A represents a plan view, B represents a sectional structural diagram taken along an X-X′ line in A, and C represents a sectional structural diagram taken along a Y-Y′ line in A.

FIGS. 11AA to 11AC corresponds to FIGS. 1A to 1AC in the first embodiment, in which the i layer 6 is formed on the substrate and, for example, a mask material layer 300 (an example of the “third mask material layer” according to the scope of claims) made of SiO₂, the mask material layer 7 made of SiN, the mask semiconductor layer 8 made of silicon-germanium (SiGe), and the mask semiconductor layer 9 made of SiO₂ are sequentially deposited.

Next, as shown in FIGS. 11BA to 11BC corresponding to FIGS. 1CA to 1CC in the first embodiment, using the silicon-germanium (SiGe) layer 8 and the SiO₂ mask semiconductor layer 9 as masks, the SiN layer 7, the SiO₂ mask material layer 300, and the i layer 6 are formed by RIE and the SiGe layer 8 and the SiO₂ layer 9 left on the SiN layer 7 are removed.

Subsequent steps are the same as those subsequent to FIGS. 1DA to 1DC in the first embodiment.

The present embodiment provides the following features.

In addition to the features of the third embodiment, by forming the mask material layer 300 (for example, a SiO₂ layer) between the semiconductor pillar 6 and the mask material layer 7 (for example, a SiN layer), process damage to the top part of the semiconductor pillar 6 can be reduced and, when subsequently forming the N⁺ layer 29 containing donor impurities by an epitaxial crystal growth method in the top part of the semiconductor pillar 6, crystal growth can be prevented from being inhibited by damage to the top part of the semiconductor pillar 6.

### Fourteenth Embodiment

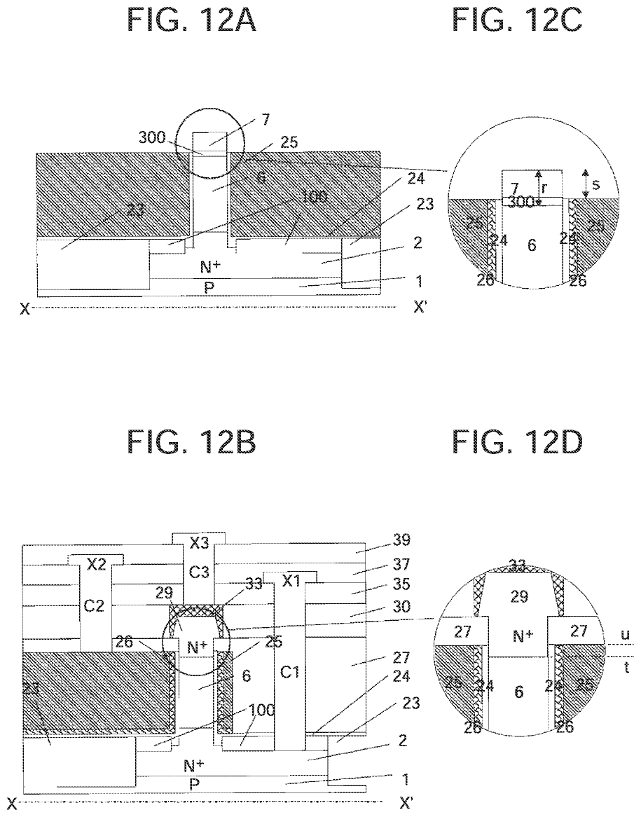

Hereinafter, using an example of an N-type transistor, a manufacturing method of an SGT according to a fourteenth embodiment of the present invention will be described with reference to FIGS. 12A to 12AD. In FIGS. 12A to 12AD, A corresponds to FIGS. 1IA to 1IC according to the first embodiment when the fourteenth embodiment is applied and represents a sectional structural diagram taken along an X-X′ line thereof, C represents an enlarged view of main parts related to the present embodiment in A, B corresponds to FIGS. 1MA to 1MC according to the first embodiment and represents a sectional structural diagram taken along an X-X′ line thereof, and D represents an enlarged view of main parts related to the present embodiment in B.

In the sectional structural diagram after completion of the process shown in FIG. 12B, in a step of etching back the gate electrode 25 shown in FIG. 12A by an RIE method so that a lower end position u of the interlayer insulator film 27 or, in other words, an upper end position u of the gate electrode 25 does not become lower than a lower end position t of the impurity region 29 as shown in FIG. 12D, a total film thickness r of the mask material layer 300 and the mask material layer 7 present on the semiconductor pillar 6 is set so that the film thickness r becomes greater than a film thickness s at which the W gate electrode layer 25 and the TiN layer (not illustrated) are etched as shown in FIG. 12C.

The present embodiment provides the following features.

In addition to the features of the thirteenth embodiment, by suitably setting the film thicknesses of the mask material layers 300 and 7 as shown in FIGS. 12A to 12AD, the W gate electrode layer 25, the TiN layer (not illustrated), and the N⁺ impurity layer 29 sufficiently overlap with each other in the vertical direction, and since an electric short-circuit between the gate electrode and the N⁺ impurity layer 29 can be suppressed, failures and variation in characteristics can be suppressed.

While one SGT has been formed on one semiconductor pillar in the embodiments according to the present invention, the present invention can also be applied to circuit formation in which two or more SGTs are formed. In circuit formation in which two or more SGTs are formed, the SGT described in the present invention is an SGT in a lowermost part of the semiconductor pillar.

While the semiconductor pillar is formed of Si in the first embodiment, the semiconductor pillar may be replaced with a semiconductor pillar made of other semiconductor materials. This similarly applies to other embodiments according to the present invention.

In addition, the N⁺ layer 2 in the lower part of the semiconductor pillar and the N⁺ layer 29 in the top part of the semiconductor pillar according to the first embodiment may be formed of P⁺ layer Si containing acceptor impurities or another semiconductor material layer. This similarly applies to other embodiments according to the present invention.

While the N⁺ layer 29 is formed using a selective epitaxial crystal growth method in the first embodiment, the N⁺ layer 29 may be formed by other methods including a method of forming the N⁺ layer 29 on the top part of the semiconductor pillar 6 by CDE (Chemical Dry Etching) and normal epitaxial crystal growth. This similarly applies to other embodiments according to the present invention.

As the mask material layer 7 in the top part and the mask material layer 21 in an outer circumferential part of the semiconductor pillar 6 according to the first embodiment, another material layer made of a single layer or made up of a plurality of layers and containing an organic material or an inorganic material may be used as long as the materials serve the purpose of the present invention. This similarly applies to other embodiments according to the present invention.

While the SiN layer 7, the silicon-germanium (SiGe) layer 8, and the SiO₂ layer 9 are used as a mask material layer and a mask semiconductor layer in the first embodiment, another material layer made of a single layer or made up of a plurality of layers and containing an organic material or an inorganic material may be used as long as the materials serve the purpose of the present invention. This similarly applies to other embodiments according to the present invention.

In addition, a material of the various wiring metal layers X1, X2, and X3 according to the first embodiment is not limited to a metal and may be a conductive material layer such as a semiconductor layer containing a large amount of an alloy, acceptor impurities, or donor impurities and may be constructed by a single layer or a combination of a plurality of layers of the conductive material layer. This similarly applies to other embodiments according to the present invention.

In addition, in the first embodiment, the TiN layer 26 is used as gate metal layer as shown in FIGS. 1IA to 1IC. As the TiN layer 26, a material layer made of a single layer or made up of a plurality of layers may be used as long as the materials serve the purpose of the present invention. The TiN layer 26 can be formed of a conductor layer such as a single metal layer or a plurality of metal layers with at least a desired work function. While a W layer is used on an outer side of the TiN layer 26 and the W layer performs the role of a metal wiring layer in the present embodiment, a single metal layer or a plurality of metal layers other than a W layer may be used. In addition, while the HfO₂ layer 24 is used as gate insulating layers, another material layer made of a single layer or made up of a plurality of layers may be used as each gate insulating layer. This similarly applies to other embodiments according to the present invention.

In the first embodiment, the semiconductor pillar 6 has a circular shape in a plan view. As the shape of a part of or the entire semiconductor pillar 6 in a plan view, a circle, an ellipse, a shape elongated in one direction, and the like can be readily formed. These descriptions similarly apply to other embodiments according to the present invention.

In addition, in the first embodiment, the N⁺ layer 2 is formed so as to be connected to the bottom part of the semiconductor pillar 6. An alloy layer made of a metal, silicide, or the like may be formed on the upper surface of the N⁺ layer 2. This also applies to a case where a P⁺ layer is formed instead of the N⁺ layer.

In addition, while SGTs are formed on the P layer substrate 1 in the first embodiment, a SOI (Silicon On Insulator) substrate may be used instead of the P layer substrate 1. Alternatively, a substrate made of other materials may be used as long as the role of a substrate is served. This similarly applies to other embodiments according to the present invention.

In addition, while SGTs that constitute a source and a drain using the N⁺ layer 2 and the N⁺ layer 29 which have conductivity of the same polarity in upper and lower positions of the semiconductor pillar 6 have been described in the first embodiment, the present invention can also be applied to tunnel SGTs having a source and a drain with different polarities. This similarly applies to other embodiments according to the present invention.

In the first embodiment, the N⁺ layer 29 is formed after forming the HfO₂ gate layer 24 and the TiN gate layer 26. In contrast, the HfO₂ gate layer 24 and the TiN gate layer 26 may be formed after forming the N⁺ layer 29. This similarly applies to other embodiments according to the present invention.

In addition, in a vertical NAND flash memory circuit, with a semiconductor pillar as a channel, a memory cell constituted of a tunnel oxide layer, a charge storage layer, an interlayer insulating layer, and a control conductor layer which surround the semiconductor pillar are formed in a plurality of stages in the vertical direction. Semiconductor pillars at both ends of the memory cells have a source line impurity layer which corresponds to a source and a bit line impurity layer which corresponds to a drain. In addition, with respect to one memory cell, if one of the memory cells on both sides serves as a source, the other memory cell serves as a drain. In this manner, a vertical NAND flash memory circuit is a type of an SGT circuit. Therefore, the present invention can also be applied to a hybrid circuit equipped with a NAND flash memory circuit.

In a similar manner, the present invention can also be applied to an inverter or a logic circuit used inside or outside a memory cell region in a magnetic memory circuit or a ferroelectric memory circuit.

The present invention enables various embodiments and modifications to be devised without departing from the broad spirit and scope of the present invention. In addition, the embodiments described above are for explaining examples of the present invention and are not intended to limit the scope of the present invention. The embodiments and the modifications described above can be arbitrarily combined. Furthermore, even if parts of constituent features of the embodiments described above are removed as necessary, such removal of constituent features is within the technical ideas of the present invention.

The manufacturing method of a pillar-shaped semiconductor device according to the present invention suppresses characteristic variations and operational failures and contributes toward quality improvement of circuits and products using an SGT.

What is claimed is:

1. A manufacturing method of a pillar-shaped semiconductor device, the a pillar-shaped semiconductor device including a SGT including, on an upper part of a substrate, a semiconductor pillar, a gate insulating layer surrounding the semiconductor pillar, a gate conductor layer surrounding the gate insulating layer, a first impurity region connected to a lower part of the semiconductor pillar, and a second impurity region connected to a top part of the semiconductor pillar, the semiconductor pillar between the first impurity region and the second impurity region constituting a channel, the method comprising the steps of:
forming the first impurity region containing donor or acceptor impurities on a surface of the substrate;
forming the semiconductor pillar on the first impurity region;
coating an entire surface with a first mask material layer;
leaving the first mask material layer on a side wall of the semiconductor pillar and exposing a surface of the first impurity region by anisotropic etching of the first mask material layer;
applying thermal or chemical oxidation to an entire stack and forming a first insulation layer that demarcates a lower end position of the gate conductor layer separately from an inter-element insulation region on the exposed surface of the first impurity region;
removing the first mask material layer left on the side wall of the semiconductor pillar by isotropic etching;
forming the gate insulating layer which surrounds the semiconductor pillar and the gate conductor layer which further surrounds the gate insulating layer; and
forming the second impurity region in a top part of the semiconductor pillar.

2. The manufacturing method of a pillar-shaped semiconductor device according to claim 1, wherein
a film thickness of the first insulation layer is set so that the film thickness of the first insulation layer is thicker than a film thickness of the gate insulating layer and a position of a lower end of the gate conductor layer is a same position as or a lower position than an upper end position of the first impurity region in the semiconductor pillar.

3. The manufacturing method of a pillar-shaped semiconductor device according to claim 1, wherein
a film thickness of the first mask material layer is smaller than a film thickness that is twice the film thickness of the gate insulating layer.

4. The manufacturing method of a pillar-shaped semiconductor device according to claim 1,
further comprising a step of, after subjecting the first mask material layer to anisotropic etching, implanting at least one of oxygen ions and impurities of a same conductivity type as the first impurity region by an ion implantation method to the entire exposed surface of the first impurity region.

5. The manufacturing method of a pillar-shaped semiconductor device according to claim 1, wherein
after forming the first insulation layer, impurities of a same conductivity type as the first impurity region are implanted by an ion implantation method to an entire region below the first insulation layer with energy that enables a sufficient amount of the impurities to be implanted.

6. The manufacturing method of a pillar-shaped semiconductor device according to claim 1,
further comprising a step of, after subjecting the first mask material layer to anisotropic etching, forming a semiconductor layer by selective epitaxial growth on an exposed surface of the substrate, wherein
the step of forming the first insulation layer involves forming the first insulation layer on the exposed surface of the substrate by thermally or chemically oxidizing the entire semiconductor layer.

7. The manufacturing method of a pillar-shaped semiconductor device according to claim 6, wherein
an oxide film growth rate of the thermal or chemical oxidation of the semiconductor layer is greater than an oxide film growth rate of the thermal or chemical oxidation of the first impurity region.

8. The manufacturing method of a pillar-shaped semiconductor device according to claim 6, wherein
the semiconductor layer is doped with impurities of a same conductivity type as the first impurity region during epitaxial growth.

9. The manufacturing method of a pillar-shaped semiconductor device according to claim 6, wherein
after forming the semiconductor layer, at least one of oxygen ions and impurities of a same conductivity type as the first impurity region are implanted by an ion implantation method to the entire semiconductor layer.

10. The manufacturing method of a pillar-shaped semiconductor device according to claim 6, wherein
a film thickness of the semiconductor layer is set such that, after forming the semiconductor layer, the first insulation layer with a desired film thickness can be formed by performing thermal or chemical oxidation which enables the entire semiconductor layer to be changed to an oxide film.
